(19) United States
(12) Patent Application Publication
(10) Pub. No.: US 2007/0114668 A1
(43) Pub. Date: May 24, 2007

(54) SEMICONDUCTOR DEVICE

(75) Inventors: Kinya Goto, Tokyo (JP); Takeshi Furusawa, Tokyo (JP); Masazumi Matsuura, Tokyo (JP); Noriko Miura, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/561,629

(22) Filed: Nov. 20, 2006

(30) Foreign Application Priority Data
Nov. 22, 2005 (JP) 2005-337355

(51) Int. Cl. H01L 23/52

(52) U.S. Cl. 257/758

(57) ABSTRACT

A semiconductor device is equipped with a semiconductor chip which has at least one layer of first insulating film formed on a substrate, and a plurality of pads arranged on a layer higher than the first insulating film. The plurality of pads on the semiconductor chip are arranged parallel to a predetermined chip edge of the semiconductor chip. The first insulating film has a reinforcement pattern in a region underneath each of the plurality of pads. In the region underneath each pad, occupancy of the reinforcement pattern in the first insulating film is within a predetermined range permitted for the region underneath each pad and occupancy of the reinforcement pattern in a whole area of a row where the reinforcement pattern is arranged in a line in a direction perpendicular to the predetermined chip edge is higher than occupancy of the reinforcement pattern in a whole area of a row where the reinforcement pattern is arranged in a line in a direction parallel to the chip edge.

### BACKGROUND OF THE INVENTION

1. Field of the Invention

The present invention relates to a semiconductor device. More specifically, it relates to a structure of a semiconductor device which has pads on a semiconductor chip surface.

2. Background Art

Recently, along with high integration and miniaturization of semiconductor devices, there has been a growing demand for reduction of wire capacitance in the semiconductor chips. Techniques for reducing wire capacitance include one which decreases a dielectric constant of an interlayer insulating film by using a low-dielectric film (hereinafter referred to as a “low-k film”) as the interlayer insulating film. However, decreases in the dielectric constant of the insulating film tend to result in reduced mechanical strength of the insulating film. Thus the use of a low-k film as the interlayer insulating film to reduce the wire capacitance can possibly cause various problems including (1) decreases in peel resistance during CMP (Chemical Mechanical Polishing), (2) deterioration of pad shape due to probing during in-line testing, (3) expansion or contraction of resin during a packaging process, and (4) peeling around pads due to tensile forces during wire bonding. Of the above problems, problems (2) to (4) will occur around pads.

Various structures have been conceived to ensure the mechanical strength around the pads of a semiconductor device which uses a low-k film as the interlayer insulating film. Specifically, for example, Japanese Patent Laid-Open No. 11-54544 discloses a reinforced wiring structure for use under pads to reinforce a film of low strength such as a low-k film. The reinforcement is constituted of a structure made, for example, of SiO₂ or the like and has a high mechanical strength. It is embedded in lower part of the low-strength film. The reinforcement greatly reduces the thickness of the low-strength film under the pads, and thereby reinforces the mechanical strength of the inter-metallic insulating film below the pads.

Also, a structure is known in which an insulating film with a dielectric constant of 3.5 or above and a thickness of 1.5 μm or above is placed in a layer just under pads and no via or wire is formed in that part of the insulating film which is located under pad openings. Since the insulating film of high mechanical strength is placed under the pads, this structure ensures some strength against forces in the direction in which the pads are pushed downward toward an underlying substrate (hereinafter referred to as the “pushing direction”). This ensures resistance to stylus pressure and the like caused by probing during in-line testing. Consequently, problems such as problem (2) above can be avoided, thereby preventing deterioration of pad shape.

Also, there is, for example, a structure in which a reinforcement pattern of vias and wires made of Cu, Al, or the like is placed in regions under pads made of a film of low mechanical strength such as a low-k film. The reinforcement pattern placed in this way ensures sufficient strength against forces in the direction in which the pads are peeled (hereinafter referred to as the “peeling direction”) or forces in the direction parallel to pad surfaces and films (hereinafter referred to as the “parallel direction”). This ensures resistance to expansion or contraction of resin and prevents peeling around pads due to tensile forces during wire bonding. Consequently, problems such as problems (3) and (4) above can be avoided.

However, although the use of the insulating film with a dielectric constant of 3.5 or above, for example, in a layer just under the pads ensures resistance in the pushing direction, it provides insufficient resistance to forces in the peeling direction and parallel direction. This makes it difficult to ensure sufficient strength against stress caused by expansion or contraction of resin during a packaging process or against tensile forces exerted during wire bonding.

On the other hand, the use of the reinforcement pattern just under the pads ensures resistance in the peeling direction and parallel direction. However, the Cu and Al which make up the reinforcement pattern are soft materials and have a low resistance to forces in the pushing direction. Thus, it is not possible to ensure sufficient strength against forces in the pushing direction such as stylus pressure exerted during probing. This may cause, for example, a short circuit or the like between wires.

In this way, it is difficult for conventional structures to ensure resistance to forces in the pushing direction and forces in the peeling or parallel direction, and impossible to ensure sufficient strength in either of the directions. Thus, ensuring the mechanical strength of a semiconductor device solely by layout structure of insulating film or proper arrangement of a reinforcement pattern is not sufficient to manufacture a reliable semiconductor device.

### SUMMARY OF THE INVENTION

To solve the above problems, the present invention has an object to provide a semiconductor device with such an improved structure as to ensure mechanical strength of part under pads even when using an insulating film of low mechanical strength in the semiconductor device.

According to one aspect of the present invention, a semiconductor device comprises a semiconductor chip which has at least one layer of first insulating film formed on a substrate, and a plurality of pads arranged on a layer higher than the first insulating film. The plurality of pads on the semiconductor chip are arranged parallel to a predetermined chip edge of the semiconductor chip. The first insulating film has a reinforcement pattern in a region underneath each of the plurality of pads. In the region underneath each pad, occupancy of the reinforcement pattern in the first insulating film is within a predetermined range permitted for the region underneath each pad and occupancy of the reinforcement pattern in a whole area of a row where the reinforcement pattern is arranged in a line in a direction perpendicular to the predetermined chip edge is higher than occupancy of the reinforcement pattern in a whole area of a row where the reinforcement pattern is arranged in a line in a direction parallel to the chip edge.

Other and further objects, features and advantages of the invention will appear more fully from the following description.

### BRIEF DESCRIPTION OF THE DRAWINGS

FIG. 1 is a schematic top view illustrating a semiconductor device according to a first embodiment of the present invention;

FIGS. 2A to 2C are schematic diagrams illustrating a structure near a sub-pad region of the semiconductor device according to the first embodiment of the present invention;

FIG. 3 is a flowchart illustrating a manufacturing method of the semiconductor device according to the first embodiment of the present invention;

FIG. 4 is a schematic diagram illustrating a state of the semiconductor device in its manufacturing process according to the first embodiment of the present invention;

FIG. 5 is a schematic diagram illustrating a state of the semiconductor device in its manufacturing process according to the first embodiment of the present invention;

FIG. 6 is a schematic diagram illustrating a state of the semiconductor device in its manufacturing process according to the first embodiment of the present invention;

FIG. 7 is a schematic diagram illustrating a state of the semiconductor device in its manufacturing process according to the first embodiment of the present invention;

FIG. 8 is a schematic diagram illustrating a state of the semiconductor device in its manufacturing process according to the first embodiment of the present invention;

FIG. 9 is a schematic diagram illustrating a state of the semiconductor device in its manufacturing process according to the first embodiment of the present invention;

FIGS. 10A and 10B are schematic diagrams illustrating a structure near a sub-pad region of a semiconductor device according to a second embodiment of the present invention;

FIGS. 11A to 11C are schematic diagrams illustrating a structure near a sub-pad region of a semiconductor device according to a third embodiment of the present invention;

FIG. 12 is a flowchart illustrating a manufacturing method of the semiconductor device according to the third embodiment;

FIG. 13 is a schematic diagram illustrating a state of the semiconductor device in its manufacturing process according to the third embodiment of the present invention;

FIG. 14 is a schematic diagram illustrating a state of the semiconductor device in its manufacturing process according to the third embodiment of the present invention;

FIGS. 15A to 15C are schematic diagrams illustrating a structure near a sub-pad region of a semiconductor device according to a fourth embodiment of the present invention;

FIGS. 16A and 16B are schematic diagrams illustrating a structure near a sub-pad region of another semiconductor device according to the fourth embodiment of the present invention;

FIGS. 17A to 17C are schematic diagrams illustrating a structure near a sub-pad region of a semiconductor device according to a fifth embodiment of the present invention;

FIGS. 18A and 18B are schematic diagrams illustrating a structure near a sub-pad region of another semiconductor device according to the fifth embodiment of the present invention;

FIGS. 19A to 19C are schematic diagrams illustrating a structure near a sub-pad region of a semiconductor device according to a sixth embodiment of the present invention;

FIGS. 20A and 20B are schematic diagrams illustrating a structure near a sub-pad region of another semiconductor device according to the sixth embodiment of the present invention;

FIGS. 21A to 21C are schematic diagrams illustrating a structure near a sub-pad region of a semiconductor device according to a seventh embodiment of the present invention;

FIGS. 22A and 22B are schematic diagrams illustrating a structure near a sub-pad region of another semiconductor device according to the seventh embodiment of the present invention;

FIGS. 23A to 23C are schematic diagrams illustrating a structure near a sub-pad region of a semiconductor device according to an eighth embodiment of the present invention;

FIGS. 24A and 24B are schematic diagrams illustrating a structure near a sub-pad region of another semiconductor device according to the eighth embodiment of the present invention;

FIGS. 25A to 25C are schematic diagrams illustrating a structure near a sub-pad region of a semiconductor device according to a ninth embodiment of the present invention;

FIGS. 26A and 26B are schematic diagrams illustrating a structure near a sub-pad region of another semiconductor device according to the ninth embodiment of the present invention;

FIGS. 27A to 27C are schematic diagrams illustrating a structure near a sub-pad region of a semiconductor device according to a tenth embodiment of the present invention; and

FIGS. 28A and 28B are schematic diagrams illustrating a structure near a sub-pad region of another semiconductor device according to the tenth embodiment of the present invention.

### DETAILED DESCRIPTION OF THE PREFERRED EMBODIMENTS

Embodiments of the present invention will be described below with reference to the drawings. Incidentally, the same or equivalent components will be denoted by the same reference numerals among different drawings, and description thereof will be simplified or omitted.

### Semiconductor Chip According to Embodiments

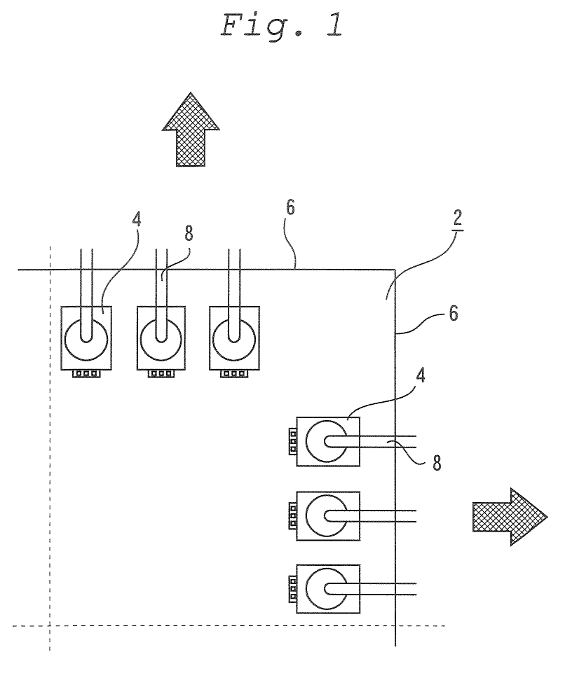

FIG. 1 is a schematic diagram illustrating a semiconductor chip according to a first embodiment of the present invention. For the sake of simplicity, only the upper right quarter of a semiconductor chip 2 is shown in FIG. 1. The semiconductor chip 2 in FIG. 1 has a plurality of pads 4 on its surface. The pads 4 are arranged parallel to chip edges 6 of the semiconductor chip 2, near the outer periphery of the semiconductor chip 2. Although three pads 4 each in a column and a row are shown schematically in FIG. 1, actually the number of pads is not limited to the number indicated in FIG. 1 and varies with the semiconductor chip. Each pad 4 is connected with a lead wire 8.

In the semiconductor chip 2, forces exerted in the peeling direction during wire bonding and forces caused by expansion or contraction of resin during packaging act in the direction perpendicular to the chip edge 6 as indicated by arrows in FIG. 1. Thus, the structures according to the embodiments described below have enhanced resistance mainly to forces in the direction perpendicular to the chip edge 6 out of forces in the peeling direction and parallel direction. Incidentally, for the sake of simplicity, a region underlying that part of the pad 4 which shows above the chip surface will be referred to hereinafter as the “sub-pad region.” The “sub-pad region” is corresponding to the “region underneath each pad” in the present invention.

The arrangement of wires and vias in each layer of the semiconductor chip 2 has the following structural limitations.

(1) The upper limits of the occupancies of both wires and vias in each sub-pad region are somewhere around 80%. Higher occupancies will decrease the mechanical strength in the pushing direction, presumably making it impossible to ensure sufficient strength against forces in the pushing direction such as stylus pressure exerted during probe testing.

(2) Preferably, the wires and vias are formed in the same layer simultaneously with other patterns formed in regions other than the sub-pad region. Thus, the shapes and arrangements of wires and vias in the sub-pad region should be set in such a way as to avoid distortion during exposure with due consideration to the shapes and arrangements of the patterns formed in regions other than the sub-pad region of the same layer. Also, for ease in manufacturing masks used for exposure, it is desirable that their shapes and arrangements should be uniform to some extent. Thus, the structure in the sub-pad region alone cannot always be laid out in such a way as to reach its upper limit of 80%.

Thus, in the following embodiments, reinforcement structures are formed in each sub-pad region taking into consideration the fact that forces in the parallel and peeling directions act mainly in the direction perpendicular to the chip edge 6 as well as restrictions on occupancy and pattern shape in each sub-pad region.

Specifically, reinforcement pattern are arranged so that in a direction perpendicular to the nearest chip edge, many of the reinforcement pattern is arranged in a row. That is, occupancy of the reinforcement pattern in a whole area of the row where the reinforcement pattern is arranged in a line in a direction perpendicular to the nearest chip edge is higher than occupancy of the reinforcement pattern in a whole area of a row where the reinforcement pattern is arranged in a line in a direction parallel to the chip edge. Hereinafter, these occupancy in a row area in the direction perpendicular is called “perpendicular-occupancy” and these in the direction parallel is called “parallel-occupancy”.

### First Embodiment

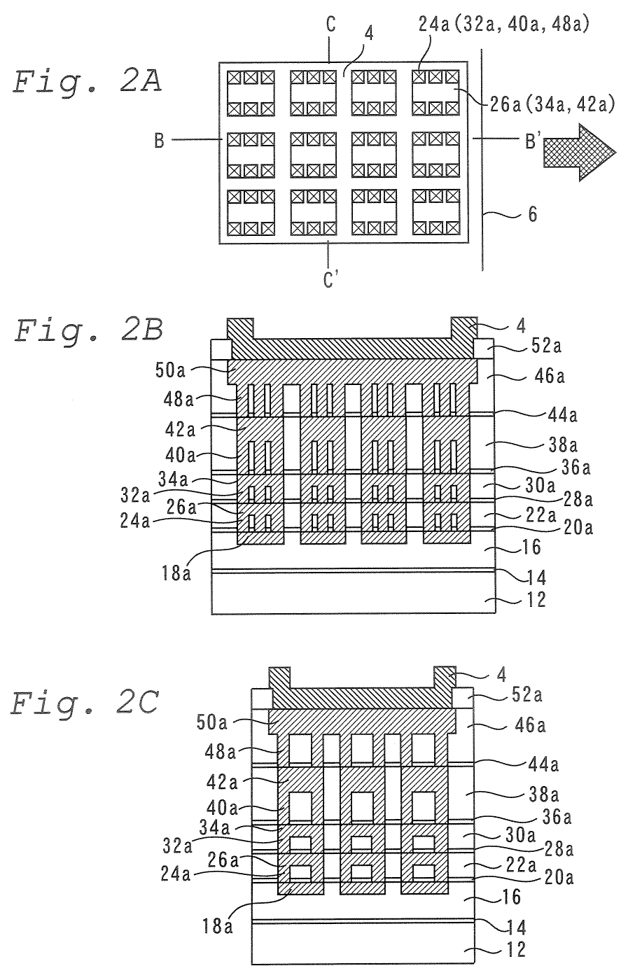

FIGS. 2A to 2C are schematic diagrams illustrating the structure near a sub-pad region of a semiconductor device 1 according to the first embodiment of the present invention. FIG. 2A is a perspective front view showing mainly an arrangement of wires and vias in the sub-pad region, FIG. 2B is a sectional view taken along line B-B′ in FIG. 2A, and FIG. 2C is a sectional view taken along line C-C′ in FIG. 2A.

The semiconductor device in FIGS. 2A to 2C has a Si substrate 12. A SiO₂ film 16 is formed on the Si substrate 12 via a thin thermally-oxidized film 14. The SiO₂ film 16 has a dielectric constant (k) of 3.5 or above and a film thickness of 200 nm. Cu wires 18a are formed on the SiO₂ film 16. The Cu wires 18a consist of Cu embedded via barrier metal (not shown) in a wiring groove formed on the SiO₂ film 16, where the barrier metal consists of 10 nm thick Ta and TaN films deposited in this order.

On surfaces of the SiO₂ film 16 and Cu wires 18a formed on the SiO₂ film 16, a low-dielectric film (hereinafter referred to as a “low-k film”) 22a is formed via a SiC film 20a. The low-k film 22a is a SiOC film with a dielectric constant (k) of less than 3.5. It is 500 nm thick. A reinforcement pattern consisting of reinforcement vias 24a connected to the Cu wires 18a and reinforcement wires 26a connected to the reinforcement vias 24a is formed penetrating the SiC film 20a and low-k film 22a in the sub-pad region. The reinforcement pattern is formed by the dual Damascene process. That is, via barrier metal (not shown) of Ta and TaN, Cu is embedded in the reinforcement vias 24a formed in the low-k film 22a and openings for the reinforcement wires 26a.

Similarly, on surfaces of the low-k film 22a and reinforcement wires 26a formed in the layer of the low-k film 22a, a low-k film 30a is formed via a SiC film 28a. The low-k film 30a is a SiOC film with a dielectric constant (k) of less than 3.5. It is 500 nm thick. A reinforcement pattern is formed in the low-k film 30a in the sub-pad region penetrating the SiC film 28a and low-k film 30a as in the case of the low-k film 22a. That is, reinforcement vias 32a similar in shape and arrangement to the reinforcement vias 24a are connected to the underlying reinforcement wires 26a and reinforcement wires 34a similar in shape and arrangement to the reinforcement wires 26a are connected to the reinforcement vias 32a.

On surfaces of the low-k film 30a and reinforcement wires 34a formed on the low-k film 30a, a SiO₂ film 38a is formed via a SiC film 36a. The SiO₂ film 38a has a dielectric constant (k) of 3.5 or above and a thickness of 1,000 nm. Vias 40a and wires 42a are formed on the SiC film 36a and SiO₂ film 38a. The vias 40a are connected to the underlying reinforcement wires 34a. As the sub-pad region is viewed from above, the vias 40a are similar in shape and arrangement to the reinforcement vias 32a and reinforcement vias 24a. The wires 42a are connected to the vias 40a. The wires 42a are similar in shape and arrangement to the reinforcement wires 34a and 26a and are connected to the vias 40a.

On surfaces of the SiO₂ film 38a and wires 42a formed on the SiO₂ film 38a, a SiO₂ film 46a is formed via a SiC film 44a. Vias 48a are formed on the SiC film 44a and SiO₂ film 46a and connected to the wires 42a. As the sub-pad region is viewed from above, the vias 48a are similar in shape and arrangement to the vias 40a and reinforcement vias 24a and 32a. The vias 48a are connected with a wire 50a. When viewed from above, the wire 50a has the same planar shape as the pad 4 and covers the via and wires in the underlying layers.

An insulating film 52a is formed on surfaces of the SiO₂ film 46a and wire 50a formed on the SiO₂ film 46a. The insulating film 52a has an opening at a location where the pad 4 is formed. The pad 4 made of aluminum is formed in the opening. The pad 4 is connected to the wire 50a in the opening.

Reinforcement patterns composed of wires and vias are formed in the sub-pad region of the semiconductor chip 2 as described above. When viewed from above, the sub-pad region measures approximately 80 μm×100 μm. The reinforcement wires 26a, reinforcement wires 34a, and wires 42a formed in the region measure approximately 3 μm×3 μm each. The spacing among the reinforcement wires 26a, reinforcement wires 34a, and wires 42a is 4 μm both in directions perpendicular and parallel to the chip edge 6.

On the other hand, the reinforcement vias 24a, reinforcement vias 32a, vias 40a, and vias 48a measure approximately 0.36 μm×0.36 μm each when viewed from above, where multiple reinforcement vias 24a and 32a or vias 40a and 48a are connected to a single wire. The spacing among each reinforcement via 24a and 32a and via 40a and via 48a is 1.32 μm in the direction perpendicular to the chip edge, and 2.64 μm in the direction parallel to the chip edge.

Although FIGS. 2A to 2C illustrate only a single sub-pad region, every sub-pad region in the semiconductor chip 2 has the same structure as in FIGS. 2A to 2C. Also, although the chip edge 6 is located along the right edge of the paper in FIG. 2A, the arrangement varies with the positions of the pads 4. For example, if the chip edge 6 is located along the top edge of the paper, the arrangement in FIG. 2A is rotated left by 90 degrees. In the entire semiconductor chip 2, each of its four sides constitutes the chip edge 6 shown in FIG. 2A.

In the sub-pad region according to the first embodiment, the reinforcement vias 24a, 32a, and the like are configured to be arranged in the direction perpendicular to the chip edge 6 with a higher occupancy. That is, the perpendicular-occupancy of the reinforcement pattern is higher than the parallel-occupancy of the reinforcement pattern.

As described above, the forces in the parallel direction and peeling direction acting near each pad 4 of the semiconductor chip 2 are oriented mainly in the direction perpendicular to the chip edge 6 as indicated by the arrow in FIG. 2A. Thus, in the structure of the reinforcement patterns in FIGS. 2A to 2C, the perpendicular-occupancy of the vias is made higher than the parallel-occupancy of the vias. This increases resistance to the forces in the direction perpendicular to the chip edge 6. On the other hand, the parallel-occupancy of the vias is smaller than the perpendicular-occupancy of the vias. This ensures that the occupancy will not exceed an allowable range in each layer of each sub-pad region while ensuring resistance to the forces in the pushing direction.

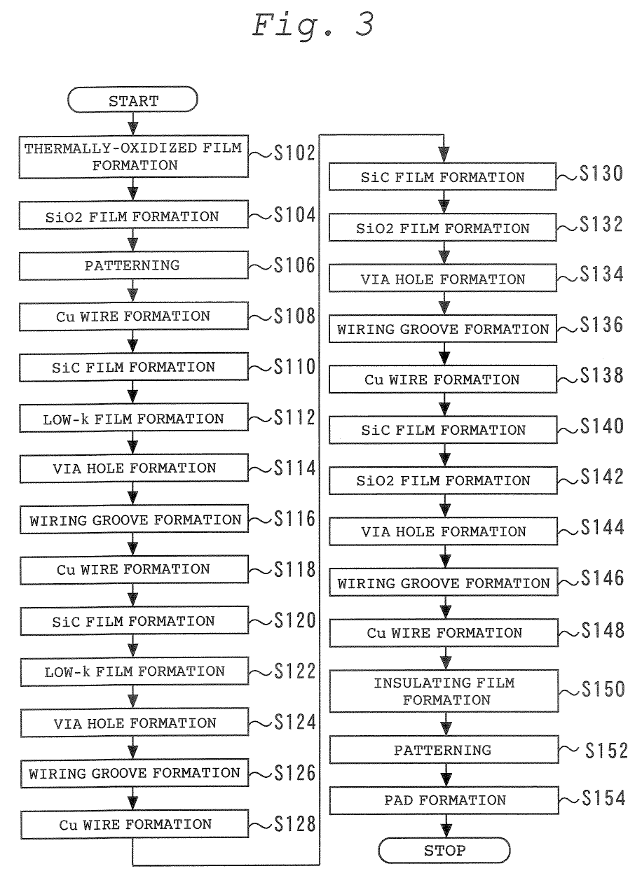

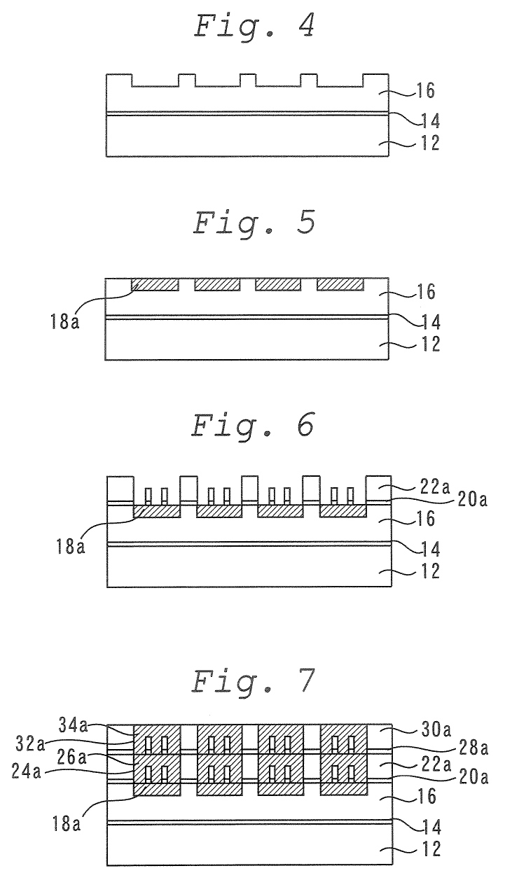

FIG. 3 is a flowchart illustrating a manufacturing method of the semiconductor device according to the first embodiment. FIGS. 4 to 9 are schematic sectional views illustrating various states of the semiconductor device in its manufacturing process. However, FIGS. 4 to 9 show only cross sections which correspond to FIG. 2B.

According to the flowchart in FIG. 3, referring to FIG. 4, the thin thermally-oxidized film 14 is formed on the Si substrate 12 (Step S102). Next, the SiO₂ film 16 is formed on the thermally-oxidized film 14 (Step S104). The SiO₂ film 16 is 200 nm in thickness. Next, the SiO₂ film 16 is patterned (Step S106). In this case, a mask is formed on the SiO₂ film 16 by photolithography and the SiO₂ film 16 is patterned by dry etching using the mask. Consequently, the wiring groove is formed in a position where the Cu wires 18a will be formed on the SiO₂ film 16.

Next, referring to FIG. 5, the Cu wires 18a are formed on the SiO₂ film 16 (Step S108). For that, first, barrier metals (not shown) of Ta and TaN are deposited 10 nm each on the patterned surface of the SiO₂ film 16 by sputtering. Then, a Cu seed film (not shown) 100 nm in thickness is deposited by sputtering and a Cu film 600 nm in thickness is deposited by Cu plating. Subsequently, the Cu is removed from parts other than the wiring grooves by CMP (Chemical Mechanical Polishing) to form the Cu wires 18a near the surface of the SiO₂ film 16.

Next, referring to FIG. 6, the SiC film 20a is formed on the SiO₂ film 16 (Step S110), and then the low-k film 22a is formed (Step S112). The low-k film 22a is a SiOC film with a dielectric constant (k) of less than 3.5. It is formed to a film thickness of 500 nm. Next, via holes are formed in the low-k film 22a and SiC film 20a (Step S114). The via holes are openings formed in locations where the reinforcement vias 24a will be formed. Specifically, a resist mask with openings provided in locations corresponding to the locations of the reinforcement vias 24a is formed on the surface of the low-k film 22a by photolithography and the openings (vias) are formed in the low-k film 22a and SiC film 20a by dry etching using the resist mask. Next, wiring grooves are formed in the low-k film 22a (Step S116). The wiring grooves are openings formed in those locations of the low-k film 22a where wires will be formed. Specifically, a resist mask with openings provided in locations of the reinforcement wires 26a is formed by photolithography and the wiring grooves are formed by dry-etching the low-k film 22a using the resist mask.

Next, referring to FIG. 7, the reinforcement vias 24a and reinforcement wires 26a are formed (Step S118). For that, barrier metals (not shown) of Ta and TaN and a Cu seed film (not shown) are formed in sequence, by sputtering, in the via holes and wiring grooves formed in Steps S114 and S116. Then the via holes and wiring grooves are filled with Cu by Cu plating. Furthermore, barrier metals and the Cu are removed from parts other than the via holes and wiring grooves by CMP (Chemical Mechanical Polishing). This produces a reinforcement pattern consisting of the reinforcement vias 24a and reinforcement wires 26a of dual Damascene structure.

Next, Steps S110 to S118 are repeated to form a layer of the low-k film 30a containing a reinforcement pattern consisting of a second layer of reinforcement vias 32a and reinforcement wires 34a. Specifically, the SiC film 28a and low-k film 30a are formed in sequence on the low-k film 22a surface (Steps S120 and S122). Then, via holes and wiring grooves are formed by repeating photolithography and dry etching (Steps S124 and S126) and Cu is embedded via barrier metal (Step S128) to produce a reinforcement pattern consisting of the reinforcement vias 32a and reinforcement wires 34a of dual Damascene structure.

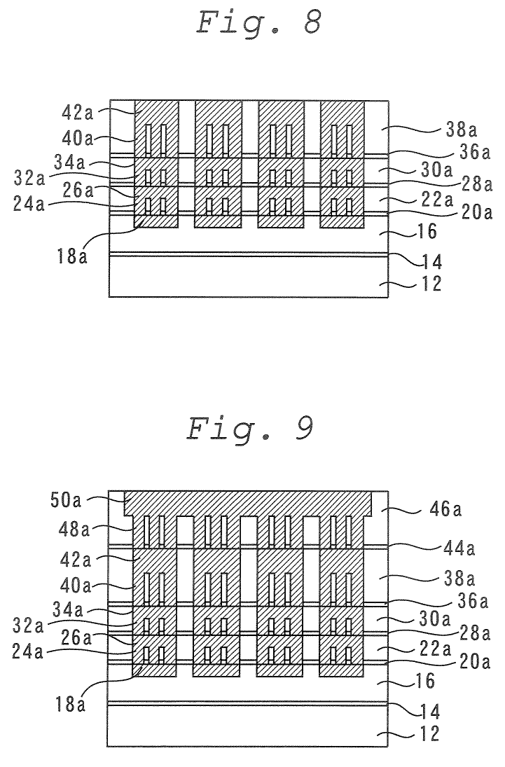

Next, referring to FIG. 8, the SiC film 36a is formed on the low-k film 30a (Step S130) and the SiO₂ film 38a is formed on it (Step S132). The SiO2 film 38a is an oxidized silicon film with a dielectric constant of 3.5 or above. It is formed to a film thickness of approximately 1,000 nm. Next, via holes and wiring grooves are formed by photolithography and dry etching (Steps S134 and S136) as in the case of Steps S114 and S116. Subsequently, in the via holes and wiring grooves, barrier metal (not shown) and a seed film (not shown) are formed by sputtering and Cu is embedded by Cu plating. Furthermore, excess barrier metal and Cu are removed from the surface of the SiO₂ film 38a by CMP to produce the vias 40a and wires 42a of dual Damascene structure (Step S138).

Next, referring to FIG. 9, Steps S130 to S138 are repeated to form the vias 48a and wire 50a in a higher layer. Specifically, the SiC film 44a and SiO₂ film 46a are formed in sequence on the SiO₂ film 38a (Steps S140 and S142) and then via holes and wiring grooves are formed (Steps S144 and S146). Subsequently, Cu is embedded in the via holes and wiring grooves via barrier metal (not shown) and unnecessary barrier metal and Cu are removed by CMP to produce the vias 48a and wire 50a. Incidentally, the wire 50a in the uppermost layer has a shape different from those of the wires 42a and reinforcement wires 34a and 26a, and has a planar pattern similar to that of the pad 4 formed on it.

Next, the insulating film 52a is formed by laminating a SiN film, SiO₂ film, and the like (Step S150). Then, the insulating film 52a is patterned and an opening is formed in the location where the pad 4 will be formed (Step S152). Next, the pad 4 is formed in the opening (Step S154). Specifically, first an aluminum film of 800 nm in thickness is formed over the entire surface by sputtering. Then, the pad 4 is shaped into a desired structure by photolithography and dry etching. Subsequently, a passivation film is deposited, a pad 4 location is opened and a protective layer of polyimide is formed, as required. Furthermore, an opening is produced in the pad 4 location in the polyimide layer. In this way, the semiconductor device according to the first embodiment is produced.

Only the structure underlying a single pad 4 has been illustrated in relation to the manufacturing method described above, but simultaneously with the process of forming vias or wires in each layer, necessary vias and wires are formed in regions other than the sub-pad region.

As described above, in the structure according to the first embodiment, to ensure resistance in the pushing direction, the patterns of the reinforcement vias 24a and 32a and vias 40a and 48a are arranged in such a way as to maximize the perpendicular-occupancy of the reinforcement pattern within the range of occupancy allowed for each sub-pad region and within the range permitted in consideration of the shape of the other patterns formed in the same layer. Consequently, the structure has a high resistance to expansion and contraction of resin, tensile forces during wire bonding, and other forces exerted greatly in the direction perpendicular to the chip edge 6. This gives a semiconductor device high resistance to forces in the direction perpendicular to the chip edge 6 while minimizing drops in resistance in the pushing direction, and thereby makes it possible to provide a reliable semiconductor device.

Incidentally, according to the first embodiment, two layers of the low-k films 22a and 30a and two layers of the insulating films 38a and 46a are laminated on the SiO₂ film 16. However, the present invention is not limited to this, and a single layer or more than two layers of a low-k film or insulating film may be stacked. In that case, a desired number of layers can be obtained by adjusting the repeating count of Steps S110 to S118 (or S120 to S128) or Steps S130 to S138 of the flowchart in FIG. 3.

Also, according to the first embodiment, a reinforcement pattern consisting of the reinforcement vias 24a or 32a and reinforcement wires 26a or 34a is formed in each low-k film 22a or 30a. However, the present invention is not limited to this. When two or more low-k films are laminated, a reinforcement pattern consisting of reinforcement vias and reinforcement wires may be formed in at least one layer in the sub-pad region while forming, for example, conventional patterns in the other layers in the sub-pad region.

Also, the types, thickness, and manufacturing method of the films described in the first embodiment do not limit the present invention. They can be selected as required according to the semiconductor chip to be produced. According to the present invention, other films, thickness, and manufacturing method may be used as long as a reinforcement pattern such as those formed in layers of low-k films 22a and 30a is provided in each sub-pad region of a low-k film or other film with a low mechanical strength.

Also, according to the present invention, the configuration of the reinforcement pattern is not limited to the arrangement in FIGS. 2A to 2C. The reinforcement pattern can be changed as required depending on the size of the semiconductor chip, the resulting size of the sub-pad region, the strength of low-k films, and so on. According to the present invention, to ensure resistance in the pushing direction, the reinforcement patterns only need to be arranged in such a way that their perpendicular-occupancy of the reinforcement pattern will be higher than the occupancy along the chip edge 6 within the range of occupancy allowed for each sub-pad region and within the range permitted in consideration of the shape of the other patterns formed in the same layer.

Incidentally, for example, in the first embodiment, the low-k films 22a or 30a correspond to the “first insulating film” according to the present invention, the chip edge 6 in FIGS. 2A to 2C corresponds to the “predetermined chip edge” according to the present invention in relation to the pad 4 shown in FIGS. 2A to 2C. Also, for example, the reinforcement pattern containing the reinforcement vias 24a in the layer of the low-k film 22a or the reinforcement pattern containing the reinforcement vias 32a in the layer of the low-k film 30a correspond to the “reinforcement pattern” according to the present invention.

### Second Embodiment

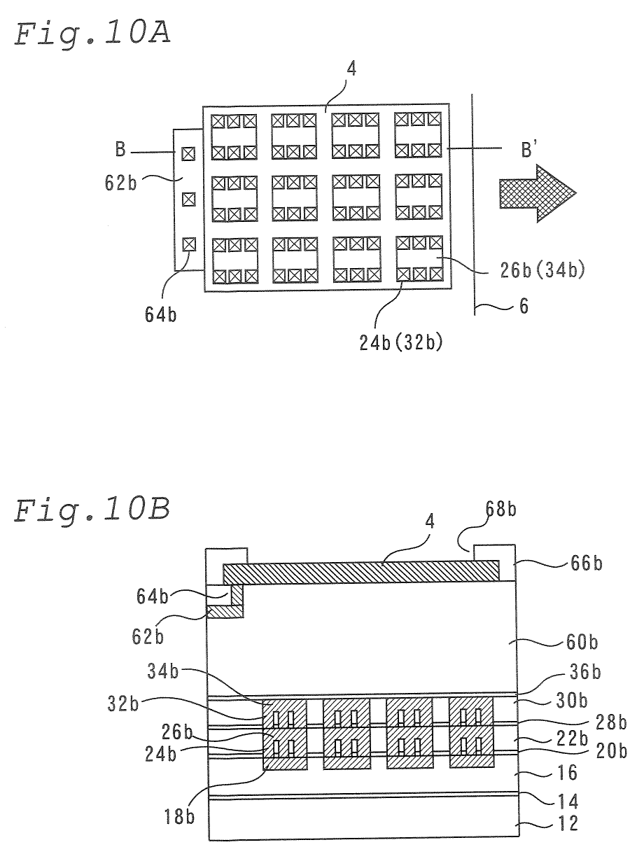

FIGS. 10A and 10B are schematic diagrams illustrating a structure near a sub-pad region of a semiconductor device according to a second embodiment of the present invention. FIG. 10A is a perspective front view showing mainly an arrangement of wires and vias in the sub-pad region and FIG. 10B is a sectional view taken along line B-B′ in FIG. 10A. The semiconductor device in FIGS. 10A and 10B has the same structure as the semiconductor device in FIGS. 2A to 2C except that an insulating film 60b is formed instead of the SiO₂ film 38a, SiO₂ film 46a, and SiC film 44a in upper layers; that an insulating film 66b is formed instead of the insulating film 52a; and that the insulating film 60b contains wires 62b and vias 64b rather than the vias 40a and 48a and the wires 42a and 50a.

Specifically, in the semiconductor device in FIGS. 10A and 10B, a SiO₂ film 16 is formed on a Si substrate 12 via a thermally-oxidized film 14 and Cu wires 18b are formed on the SiO₂ film 16, as is the case with the semiconductor device in FIGS. 2A to 2C. A low-k film 22b is formed via a SiC film 20b on the SiO₂ film 16 on which the Cu wires 18b are formed. A reinforcement pattern is formed on the low-k film 22b, where the reinforcement pattern consists of reinforcement vias 24b and reinforcement wires 26b connected with each other. Similarly, a low-k film 30b is formed on the low-k film 22b via a SiC film 28b. Also, a reinforcement pattern is formed in the layer of the low-k film 30b, where the reinforcement pattern consists of reinforcement vias 32b and reinforcement wires 34b connected with each other. The reinforcement patterns have the same arrangement as the semiconductor device in FIGS. 2A to 2C.

An insulating film 60b is formed on the low-k film 30b via a SiC film 36b. The insulating film 60b has a dielectric constant (k) of 3.5 or above. It is formed in place of the SiO₂ films 38a and 46a in FIGS. 2A to 2c. Incidentally, although a single layer of the insulating film 60b is illustrated in FIGS. 10A and 10B, two or more layers may be laminated. The insulating film 60b has a total thickness of 1,000 nm or more. Wires 62b which make electrical connection with other parts are formed on the insulating film 60b. Vias 64b are formed on the wires 62b. Besides, an insulating film 66b is formed on each pad 4 and an opening 68b is formed in the location of the pad 4. The wires 62b and vias 64b are formed in regions other than the sub-pad region under the opening 68b, but not in the sub-pad region. Electrical connection with the pad 4 is secured by means of the vias 64b and wires 62b.

The semiconductor device in FIGS. 10A and 10B can be manufactured according to the flowchart in FIG. 3. However, in the via formation and wire formation processes in Steps S134 to S138 and Steps S144 to S148, the vias and wires are not formed in the sub-pad region, and they are formed in necessary locations in other parts. Also, in these processes, the wires 62b and vias 64b are formed at the same time. This makes it possible to manufacture the semiconductor device shown in FIGS. 10A and 10B.

As described above, with the semiconductor device in FIGS. 10A and 10B, as in the case of the first embodiment, the reinforcement pattern consisting of reinforcement vias 24b and reinforcement wires 26b is formed in the low-k film 22b while the reinforcement pattern consisting of reinforcement vias 32b and reinforcement wires 34b is formed in the low-k film 30b. The reinforcement patterns allow the semiconductor device in FIGS. 10A and 10B to secure strength in the direction perpendicular to the chip edge 6. Also, in the semiconductor device in FIGS. 10A and 10B, the insulating film 60b has a dielectric constant (k) of 3.5 or above and a high mechanical strength. No wire or via is formed in that region of the insulating film 60b which is located in the sub-pad region. Consequently, even if the occupancy of the wires and vias in the sub-pad region is increased to its maximum allowable value, it is possible to ensure a structure which is strong in the pushing direction. Thus, the second embodiment of the present invention ensures resistance to expansion and contraction of resin and tensile forces during wire bonding and ensures resistance to forces in the pushing direction during in-line testing or probe testing more reliably.

Incidentally, for example, in the second embodiment, the low-k films 22b and 30b correspond to the “first insulating film” according to the present invention, the chip edge 6 in FIG. 10A corresponds to the “predetermined chip edge” according to the present invention in relation to the pad 4 shown in FIGS. 10A and 10B. Also, for example, the reinforcement pattern containing the reinforcement vias 24b in the layer of the low-k film 22b and the reinforcement pattern containing the reinforcement vias 32b in the layer of the low-k film 30b correspond to the “reinforcement pattern” according to the present invention. Also, for example, the insulating film 60b corresponds to the “second insulating film” according to the present invention.

### Third Embodiment

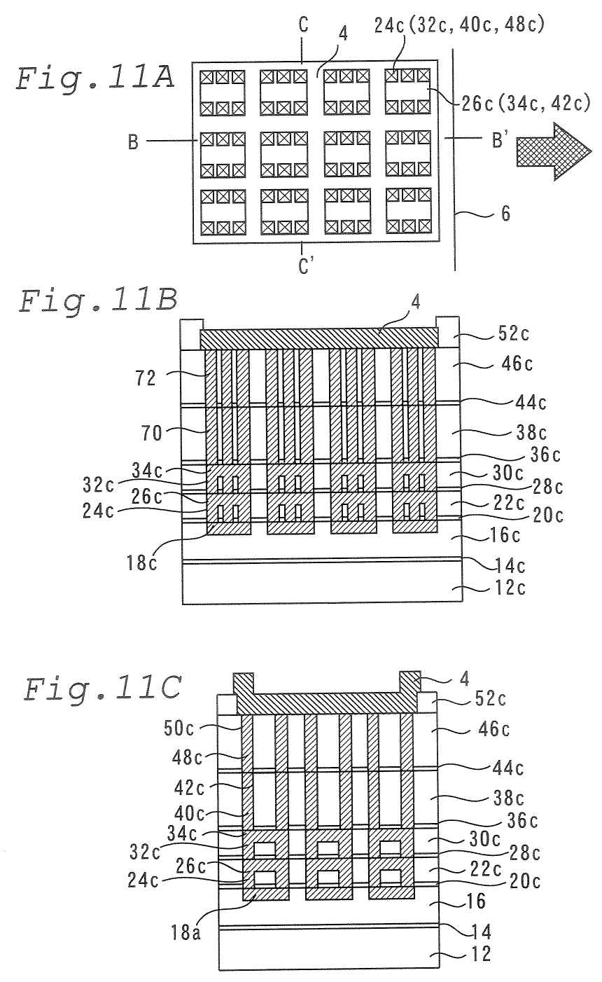

FIGS. 11A to 11C are schematic diagrams illustrating a structure near a sub-pad region of a semiconductor device according to a third embodiment of the present invention. FIG. 11A is a perspective front view showing mainly an arrangement of wires and vias in the sub-pad region and FIG. 11B is a sectional view taken along line B-B′ in FIG. 11A, and FIG. 11C is a sectional view taken along line C-C′ in FIG. 11A. The semiconductor device in FIGS. 11A to 11C has the same structure as the semiconductor device in FIGS. 2A to 2C except that the semiconductor device in FIGS. 11A to 11C has reinforcement patterns 70 and 72 made of tungsten instead of the vias 40a and 48a and the wires 42a and 50a shown in FIGS. 2A to 2C.

Specifically, in the semiconductor device in FIGS. 11A to 11C, a SiO₂ film 16 is formed on a Si substrate 12 via a thermally-oxidized film 14 and Cu wires 18c is formed on it, as is the case with the semiconductor device in FIGS. 2A to 2C. On the SiO₂ film 16 on which the Cu wires 18c are formed, a low-k film 22c is formed via a SiC film 20c and a low-k film 30c is formed via a SiC film 28c. A reinforcement pattern is formed in each layer of the low-k films 22c and 30c. Also, a SiO₂ film 38c is formed on the low-k film 30c via a SiC film 36c. Besides, a SiO₂ film 46c is formed on the SiO₂ film 38c via a SiC film 44c.

Reinforcement patterns 70 and 72 made of tungsten are formed, respectively, in those regions of the SiO₂ film 38c and SiO₂ film 46c which are located in the sub-pad region. Specifically, the reinforcement pattern 70 consisting of tungsten vias is formed penetrating the SiC film 36c and SiO₂ film 38c, where the reinforcement pattern 70 is connected underneath with the reinforcement wires 34c. Also, the reinforcement pattern 72 to be connected underneath with the reinforcement pattern 70 is formed penetrating the SiC film 44c and SiO₂ film 46c.

The structure of the reinforcement patterns formed in the layers of the low-k films 22c and 30c is the same as that of the semiconductor device in FIGS. 2A to 2C. Specifically, as shown in FIGS. 11A to 11C, they are arranged in such a way as to maximize the perpendicular-occupancy of the in each sub-pad region within the range permitted in terms of resistance to forces in the pushing direction and in consideration of the shape of the other patterns formed in the same layer. Also, the reinforcement patterns 70 and 72 formed in the layers of the SiO₂ film 38c and SiO₂ film 46c are similar in shape and arrangement to reinforcement vias 24c and 32c when viewed from above. Specifically, they are arranged in such a way as to maximize the perpendicular-occupancy of the vias in each sub-pad region within the range permitted in terms of the resistance to forces in the pushing direction and in consideration of the shape of the other patterns formed in the same layer.

The tungsten used for the reinforcement patterns 70 and 72 is a material harder than Cu or Al. Thus, the use of the reinforcement patterns 70 and 72 consisting of tungsten vias makes it possible to increase the mechanical strength in the sub-pad region. The arrangements of the reinforcement patterns 70 and 72 are the same as the other reinforcement vias. That is, they are arranged in such a way as to maximize the perpendicular-occupancy of the within the range allowed for each sub-pad region. Thus, the structure of the semiconductor device in FIGS. 11A to 11C increases resistance to the forces in the peeling direction and parallel direction and secures resistance to the forces in the pushing direction.

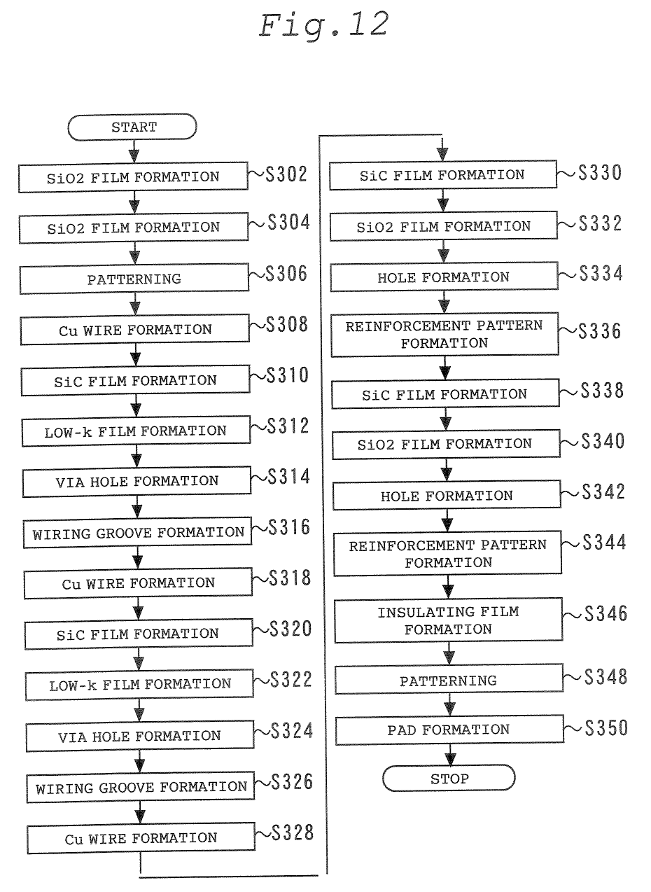

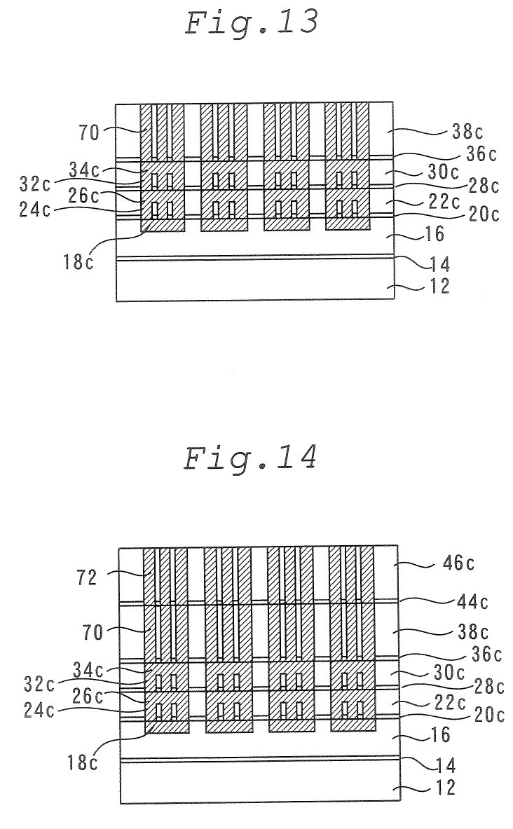

FIG. 12 is a flowchart illustrating a manufacturing method of the semiconductor device according to the third embodiment. FIGS. 13 and 14 are schematic sectional views illustrating various states of the semiconductor device in its manufacturing process. However, FIGS. 13 and 14 show only cross sections which correspond to FIG. 11B. The flowchart in FIG. 12 is the same as the flowchart in FIG. 3 except that Steps S136 and S146 of the flowchart in FIG. 3 are not performed and that tungsten vias are formed instead of the Cu wires formed in Steps S138 and S148.

Specifically, referring to FIG. 13, by the same method as in Steps S102 to S128, layers of insulating films are formed on the Si substrate 12 and reinforcement patterns are formed in the low-k films 22c and 30c (Steps S302 to S328). Then, the SiO₂ film 38c is formed on the low-k film 30c via the SiC film 36c (Steps S330 and S332). Subsequently, holes are formed in the same locations as the reinforcement vias 24c and 32c by penetrating the SiO₂ film 38c and SiC film 36c (Step S334). Next, the reinforcement pattern 70 is formed (Step S336). Specifically, tungsten is embedded in the holes by W-CVD method (Chemical Vapor Deposition). Subsequently, excess tungsten is removed by CMP to complete the reinforcement pattern 70.

Similarly, referring to FIG. 14, the SiC film 44c and SiO₂ film 46c are deposited in sequence on the SiO₂ film 38c (Steps S338 and S340). Subsequently, holes are formed in the same locations as the reinforcement pattern 70 by penetrating the SiO₂ film 46c and SiC film 44c (Step S342). Tungsten is embedded in the via holes and excess tungsten is removed by CMP to form the reinforcement pattern 72 consisting of tungsten vias (Step S344). Subsequently, the pad 4 is formed in the same manner as in Steps S150 to S154, and thus the semiconductor device shown in FIGS. 11A to 11C is produced.

As described above, with the semiconductor device according to the third embodiment, the reinforcement patterns 70 and 72 consisting of tungsten vias are formed on the SiO₂ film 38c and SiO₂ film 46c in upper layers. The reinforcement patterns are arranged in such a way as to maximize the perpendicular-occupancy of the as is the case with the reinforcement vias 24c and 32c in the low-k films 22c and 30c. This increases resistance to expansion and contraction of resin and tensile forces during wire bonding. Also, the use of tungsten, which is a hard material, in the reinforcement patterns 70 and 72 increases resistance to forces exerted in the pushing direction during probing.

Incidentally, for example, in the third embodiment, the low-k films 22c and 30c correspond to the “first insulating film” according to the present invention, the chip edge 6 in FIGS. 11A to 11C corresponds to the “predetermined chip edge” according to the present invention in relation to the pad 4 shown in FIGS. 11A to 11C. Also, for example, the reinforcement pattern containing the reinforcement vias 24c in the layer of the low-k film 22c and the reinforcement pattern containing the reinforcement vias 32c in the layer of the low-k film 30c correspond to the “reinforcement pattern” according to the present invention. Also, the SiO₂ films 38c and 46c correspond to the “third insulating film” according to the present invention while the reinforcement patterns 70 and 72 correspond to the “reinforcement vias made of tungsten.”

### Fourth Embodiment

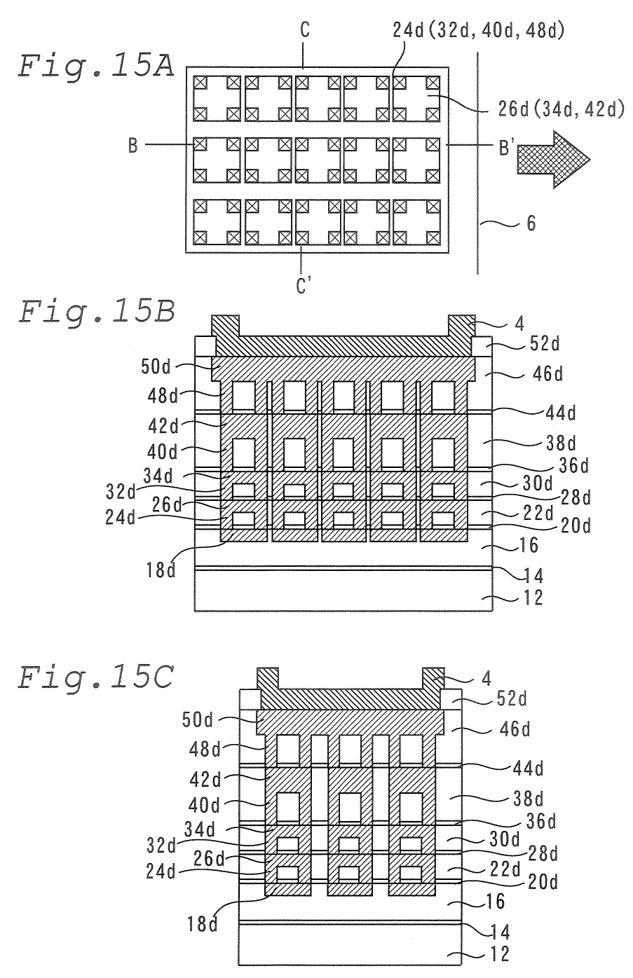

FIGS. 15A to 15C are schematic diagrams illustrating a structure near a sub-pad region of a semiconductor device according to a fourth embodiment of the present invention. FIG. 15A is a perspective front view showing mainly an arrangement of wires and vias in the sub-pad region, FIG. 15B is a sectional view taken along line B-B′ in FIG. 15A, and FIG. 15C is a sectional view taken along line C-C′ in FIG. 15A. The semiconductor device in FIGS. 15A to 15C has the same structure as the semiconductor device in FIGS. 2A to 2C except that the semiconductor device in FIGS. 15A to 15C has different arrangements of reinforcement patterns in the layers of low-k films 22d and 30d from the corresponding arrangements in FIGS. 2A to 2C.

Specifically, in the semiconductor device in FIGS. 15A to 15C, a thermally-oxidized film 14, SiO₂ film 16, SiC film 20d, low-k film 22d, SiC film 28d, low-k film 30d, SiC film 36d, SiO₂ film 38d, SiC film 44d, and SiO₂ film 46d are laminated in sequence on a Si substrate 12 as is the case with the semiconductor device in FIGS. 2A to 2C. Cu wires 18d are formed on the SiO₂ film 16. A reinforcement pattern consisting of reinforcement vias 24d and reinforcement wires 26d is formed in the layer of the low-k film 22d while a reinforcement pattern consisting of reinforcement vias 32d and reinforcement wires 34d is formed in the layer of the low-k film 30d. Vias 40d and wires 42d are formed in the layer of the SiO₂ film 38d while vias 48d and a wire 50d are formed in the layer of the SiO₂ film 46d. The pad 4 is formed in such a location as to contact the wire 50d.

As shown in FIG. 15A, when viewed from above, the reinforcement wires 26d, reinforcement wires 34d, and wires 42d are arranged in each sub-pad region in such a way as to increase the perpendicular-occupancy. The arrangement of wires in the sub-pad region is also limited by the strength in the pushing direction and wire shape in other parts. Thus, with the semiconductor device in FIGS. 15A to 15C, the perpendicular-occupancy of the reinforcement wires 26d and the like is increased within an allowable range. This increases resistance to forces in the direction perpendicular to the chip edge 6 in the sub-pad region while maintaining resistance to forces in the pushing direction.

The reinforcement vias 24d and 32d and vias 40d and 48d are connected with the reinforcement wires 26d, reinforcement wires 34d, or wires 42d. In each wire 26d, 34d, or 42d, the perpendicular-occupancy and parallel-occupancy are the same both in the case of the vias 40d and 48d. However, with the semiconductor device in FIGS. 15A to 15C, in each sub-pad region, more wires are laid in the direction perpendicular to the chip edge 6 than in the direction parallel to the chip edge 6. Consequently, in each sub-pad region, the number of reinforcement vias 24d and 32d as well as the number of vias 40d and 48d are larger in the direction perpendicular to the chip edge 6.

In this way, by maximizing the occupancy density of the wires in wire layers in the direction perpendicular to the chip edge 6 within an allowable range, it is possible to provide a structure with increased strength against forces in the direction perpendicular to the chip edge 6. Also, as described in the first embodiment, by keeping the wiring density within an allowable range, it is possible to keep the occupancy of patterns within an allowable range, taking into consideration the strength in the pushing direction. Thus, it is possible to mainly increase the strength in the direction perpendicular to the chip edge 6 while maintaining strength against forces in the pushing direction This makes it possible to provide a structure with increased resistance to forces exerted in the direction perpendicular to the chip edge 6 such as expansion and contraction of resin and tensile forces during wire bonding while maintaining high resistance to forces exerted during probing, and thereby provide a reliable semiconductor device.

Incidentally, the semiconductor device in FIGS. 15A to 15C can be manufactured by the same technique as in FIG. 3 if mask patterns used for photolithography in Steps S114, S116, S124, S126, S134, S136, S144, and S146 in FIG. 3 are changed to those suitable for the structures of the vias and wires in FIGS. 15A to 15C.

Also, in the fourth embodiment, as long as reinforcement patterns such as those of the semiconductor device in FIGS. 15A to 15C are formed in the low-k films 22d and 30d, even if the wires and the like above them have other structures, it is possible to ensure resistance to forces exerted in the direction perpendicular to the chip edge 6.

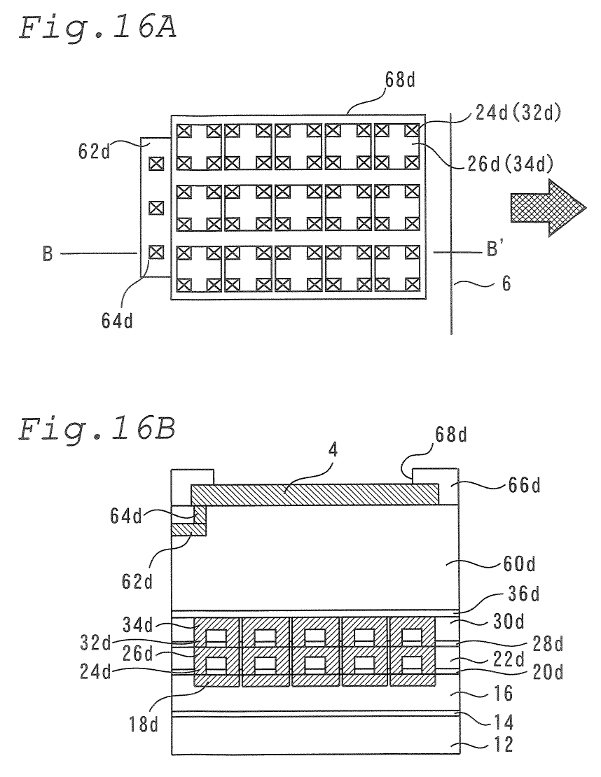

FIGS. 16A and 16B are schematic diagrams illustrating a structure near a sub-pad region of another semiconductor device according to the fourth embodiment of the present invention. FIG. 16A is a perspective front view showing mainly an arrangement of wires and vias in the sub-pad region and FIG. 16B is a sectional view taken along line B-B′ in FIG. 16A. The semiconductor device in FIGS. 16A and 16B has the same structure in terms of the sub-pad region as the semiconductor device in FIGS. 15A to 15C except that the semiconductor device in FIGS. 16A and 16B has an insulating film 60d instead of the layers of the SiO₂ film 38d, SiC film 44d, and SiO₂ film 46d on the SiC film 36d and that wires 62d and vias 64d are formed in the insulating film 60d.

Specifically, reinforcement patterns similar to those of the semiconductor device in FIGS. 15A to 15C are formed in the layers of the low-k films 22d and 30d of the semiconductor device in FIGS. 16A and 16B. The insulating film 60d with a dielectric constant (k) of 3.5 or above is formed in the sub-pad region as in the case of the semiconductor device in FIGS. 10A and 10B. The wires 62d and vias 64d are formed in the insulating film 60d, being connected with each other. The wires 62d and vias 64d are formed in regions other than the sub-pad region in such a way as to be connected to the pad 4.

The above configuration allows the semiconductor device in FIGS. 16A and 16B to increase resistance to forces in the direction perpendicular to the chip edge 6 while maintaining resistance to forces in the pushing direction, and thereby prevent deterioration of shape in the sub-pad region during probing, as described in the second embodiment.

The reinforcement patterns in the low-k films 22d and 30d of the semiconductor device in FIGS. 15A to 15C may be combined with the reinforcement patterns 70 and 72 consisting of tungsten vias according to the third embodiment. Specifically, in such a semiconductor device, the reinforcement pattern 70 consisting of tungsten vias is formed by penetrating the SiC film 36d and SiO₂ film 38d on the low-k film 30d in FIGS. 15A to 15C and the reinforcement pattern 72 is formed by penetrating the SiC film 44d and SiO₂ film 46d so as to connect to the reinforcement pattern 70. The reinforcement patterns 70 and 72 have the same shape and arrangement as the reinforcement vias 24d and 32d in the low-k films 22d and 30d when viewed from above.

In this way, by combining the reinforcement structure of the reinforcement patterns in the low-k films 22d and 30d according to the fourth embodiment with the reinforcement structure of the reinforcement patterns 70 and 72 made of tungsten according to the third embodiment, it is possible to increase resistance to forces exerted in the direction perpendicular to the chip edge 6 while maintaining strength against forces in the pushing direction.

### Fifth Embodiment

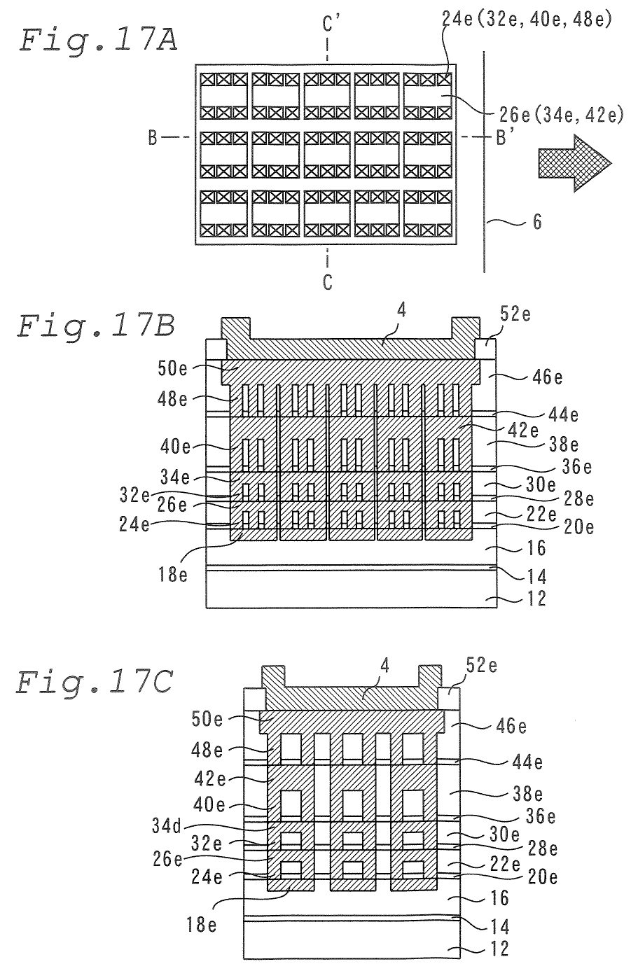

FIGS. 17A to 17C are schematic diagrams illustrating a structure near a sub-pad region of a semiconductor device according to a fifth embodiment of the present invention. FIG. 17A is a perspective front view showing mainly an arrangement of wires and vias in the sub-pad region, FIG. 17B is a sectional view taken along line B-B′ in FIG. 17A, and FIG. 17C is a sectional view taken along line C-C′ in FIG. 17A. The semiconductor device in FIGS. 17A to 17C is a combination of via arrays of the semiconductor device in FIGS. 2A to 2C and wire arrays of the semiconductor device in FIGS. 15A to 15C. Specifically, in the semiconductor device in FIGS. 17A to 17C, reinforcement wires 26e are arranged in the sub-pad region in such a way as to increase their perpendicular-occupancy. Also, reinforcement vias 24e connected to a single reinforcement wire 26e are arranged in such a way as to increase their perpendicular. A similar reinforcement pattern is formed in a layer of low-k film 30e above a low-k film 22e. Vias 40e and wires 42e in a layer of SiO₂ film 38e are similar in shape and arrangement to the reinforcement vias 24e and reinforcement wires 26e when viewed from above. Also, Vias 48e which have the same shape and arrangement as the vias 40e are formed in a layer of SiO₂ film 46e. A wire 50e of the same planar shape as the pad 4 is connected to the vias 48e.

In this way, the structure in FIGS. 17A to 17C is formed in such a way as to increase the occupancies of the vias and wires in the direction perpendicular to the chip edge 6. This makes it possible to provide a semiconductor device with increased resistance to forces in the direction perpendicular to the chip edge 6. Also, the vias and wires are arranged in such a way as to make the occupancies of the vias and wires in the direction parallel to the chip edge 6 smaller than in the perpendicular direction, thereby keeping the overall occupancy within an allowable range. This provides a semiconductor device resistant to stress in the direction perpendicular to the chip edge 6 without decreasing resistance in the pushing direction of the chip.

Incidentally, the semiconductor device in FIGS. 17A to 17C can be manufactured by the same technique as in FIG. 3 if mask patterns used for photolithography in Steps S114, S116, S124, S126, S134, S136, S144, and S146 in FIG. 3 are changed to those suitable for the structures of the vias and wires in FIGS. 17A to 17C.

Also, in the fifth embodiment, as long as reinforcement patterns such as those of the semiconductor device in FIGS. 17A to 17C are formed in the low-k films 22e and 30e, even if the wires and the like above them have other structures, it is possible to ensure resistance to forces exerted in the direction perpendicular to the chip edge 6.

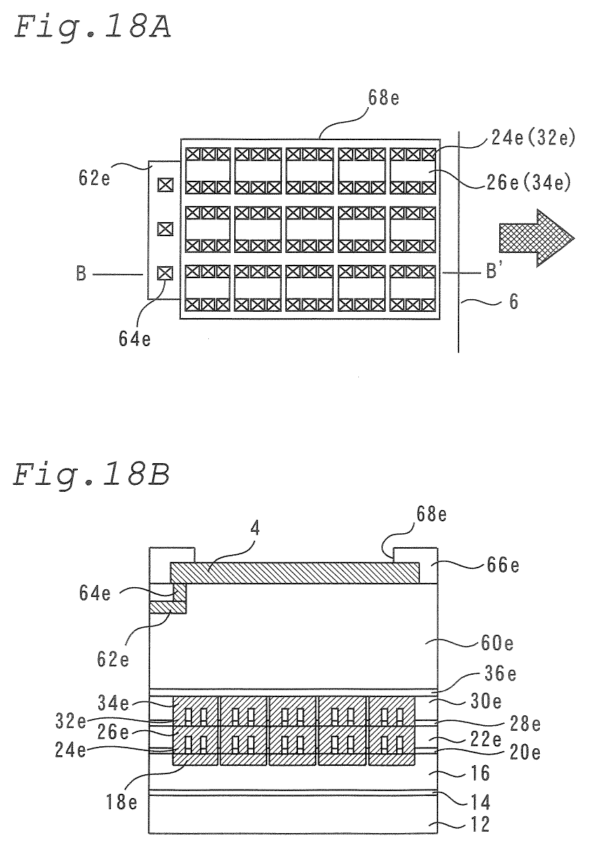

FIGS. 18A and 18B are schematic diagrams illustrating a structure near a sub-pad region of another semiconductor device according to the fifth embodiment of the present invention. FIG. 18A is a perspective front view showing mainly an arrangement of wires and vias in the sub-pad region and FIG. 18B is a sectional view taken along line B-B′ in FIG. 18A. The semiconductor device in FIGS. 18A and 18B has the same structure in terms of the sub-pad region as the semiconductor device in FIGS. 17A to 17C except that the semiconductor device in FIGS. 18A and 18B has an insulating film 60e instead of the layers of the SiO₂ film 38e, SiC film 44e, and SiO₂ film 46e on the low-k film 30e and that wires 62e and vias 64e are formed in the insulating film 60e.

Specifically, reinforcement patterns similar to those of the semiconductor device in FIGS. 17A to 17C are formed in the layers of the low-k films 22e and 30e of the semiconductor device in FIGS. 18A and 18B. The insulating film 60e with a dielectric constant (k) of 3.5 or above is formed in the sub-pad region as in the case of the second embodiment. The wires 62e and vias 64e are formed in the insulating film 60e, being connected with each other. Besides, an insulating film 66e is formed on each pad 4 and an opening 68e is formed in the location of the pad 4. The wires 62e and vias 64e are formed in regions other than the sub-pad region under the opening 68e, but not in the sub-pad region. Electrical connection with the pad 4 is secured by means of the wires 62e and vias 64e.

The above configuration allows the semiconductor device in FIGS. 18A and 18B to increase resistance to forces in the direction perpendicular to the chip edge 6 while maintaining resistance to forces in the pushing direction, and thereby prevent deterioration of shape in the sub-pad region during probing, as described in the second embodiment.

The reinforcement patterns in the low-k films 22e and 30e of the semiconductor device in FIGS. 17A to 17C may be combined with the reinforcement patterns consisting of tungsten vias according to the third embodiment. Specifically, in such a semiconductor device, the reinforcement pattern 70 consisting of tungsten vias is formed by penetrating the SiC film 36e and SiO₂ film 38e on the low-k film 30e in FIGS. 17A to 17C and the reinforcement pattern 72 is formed by penetrating the SiC film 44e and SiO₂ film 46e so as to connect to the reinforcement pattern 70. The reinforcement patterns 70 and 72 have the same shape and arrangement as the reinforcement vias 24e and 32e in the layers of the low-k films 22e and 30e when viewed from above.

In this way, by combining the reinforcement structure of the reinforcement patterns in the low-k films 22e and 30e according to the fifth embodiment with the reinforcement structure of the reinforcement patterns 70 and 72 made of tungsten vias described in the third embodiment, it is possible to further increase the resistance to forces exerted in the direction perpendicular to the chip edge 6 while maintaining the strength against forces in the pushing direction more reliably.

### Sixth Embodiment

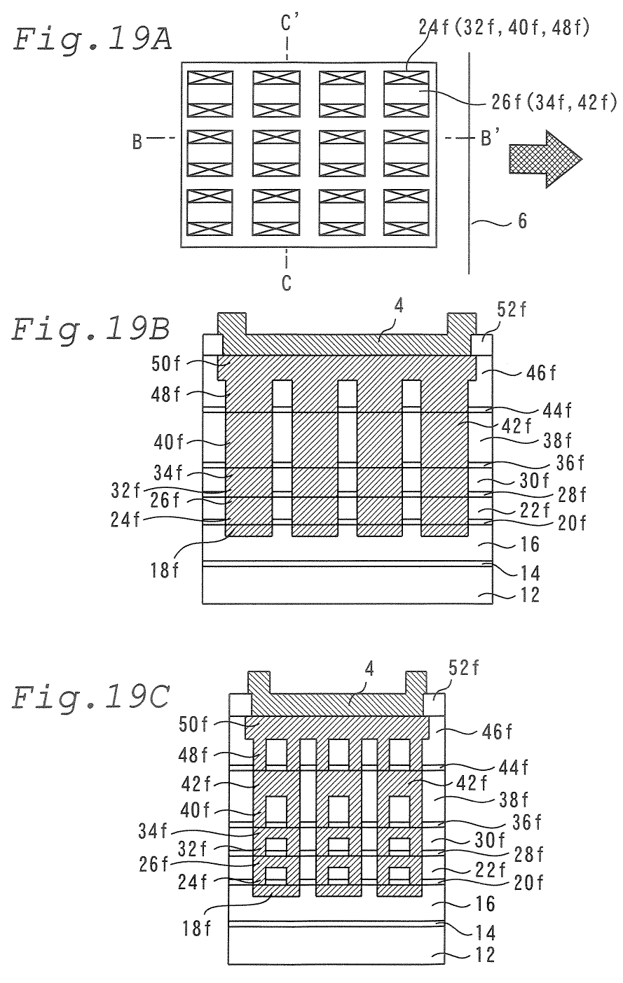

FIGS. 19A to 19C are schematic diagrams illustrating a structure near a sub-pad region of a semiconductor device according to a sixth embodiment of the present invention. FIG. 19A is a perspective front view showing mainly an arrangement of wires and vias in the sub-pad region, FIG. 19B is a sectional view taken along line B-B′ in FIG. 19A, and FIG. 19C is a sectional view taken along line C-C′ in FIG. 19A. The semiconductor device in FIGS. 19A to 19C is the same as the semiconductor device in FIGS. 2A to 2C and differs only in the shape and arrangement of reinforcement vias.

Specifically, in the semiconductor device in FIGS. 19A to 19C, reinforcement vias 24f have a rectangular shape with the long sides placed in the direction perpendicular to the chip edge 6 when viewed from above. The long side of the reinforcement vias 24f is equal to the one side of reinforcement wires 26f. The short side of the reinforcement vias 24f is equal to the side of the reinforcement vias 24a in FIGS. 2A to 2C. The reinforcement wires 26f are equal in shape to the reinforcement wires 26a in FIGS. 2A to 2C.

A similar reinforcement pattern is formed in a layer of low-k film 30f. In a layer of SiO₂ film 38f, reinforcement vias 40f of the same shape as the reinforcement vias 24f when viewed from above are arranged in the same pattern as the reinforcement vias 24f. Reinforcement wires 42f of the same shape as the reinforcement wires 26f are arranged in the same pattern, being connected to the reinforcement vias 40f. Similarly, vias 48f of the same shape as the reinforcement vias 40f are arranged in a layer of SiO₂ film 46f. A wire 50f of a planar shape to be connected to the pad 4 is formed, being connected with the reinforcement vias 48f.

As described above, according to the sixth embodiment, the reinforcement vias 24f have a rectangular shape with the long sides placed in the direction perpendicular to the chip edge 6 to ensure a high perpendicular-occupancy of vias. On the other hand, the vias have short sides in the direction parallel to the chip edge 6 to reduce the overall occupancy of the vias in the sub-pad region. Thus, the semiconductor device in FIGS. 19A to 19C can increase the resistance to forces exerted in the direction perpendicular to the chip edge 6 while maintaining the strength against forces in the pushing direction.

Incidentally, the semiconductor device in FIGS. 19A to 19C can be manufactured by the same technique as in FIG. 3 if mask patterns used for photolithography in Steps S114, S116, S124, S126, S134, S136, S144, and S146 in FIG. 3 are changed to those suitable for the structures of the vias and wires in FIGS. 19A to 19C.

Also, in the sixth embodiment, as long as reinforcement patterns such as those of the semiconductor device in FIGS. 19A to 19C are formed in the low-k films 22f and 30f, even if the wires and the like above them have other structures, it is possible to ensure resistance to forces exerted in the direction perpendicular to the chip edge 6.

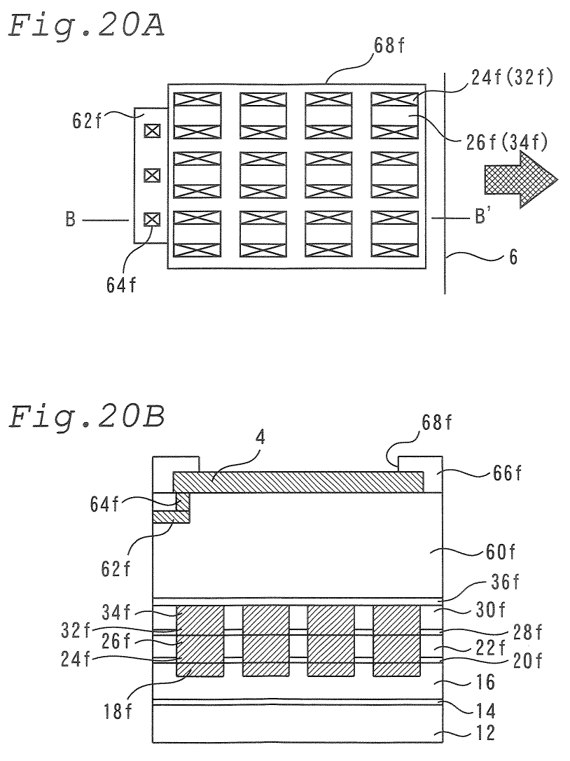

FIGS. 20A and 20B are schematic diagrams illustrating a structure near a sub-pad region of another semiconductor device according to the sixth embodiment of the present invention. FIG. 20A is a perspective front view showing mainly an arrangement of wires and vias in the sub-pad region and FIG. 20B is a sectional view taken along line B-B′ in FIG. 20A. The semiconductor device in FIGS. 20A and 20B has the same structure in terms of the sub-pad region as the semiconductor device in FIGS. 19A to 19C except that the semiconductor device in FIGS. 20A and 20B has an insulating film 60f instead of the layers of the SiO₂ film 38f, SiC film 44f, and SiO₂ film 46f and that wires 62f and vias 64f are formed in the insulating film 60f.

Specifically, reinforcement patterns similar to those of the semiconductor device in FIGS. 19A to 19C are formed in the layers of the low-k films 22f and 30f of the semiconductor device in FIGS. 20A and 20B. The insulating film 60f with a dielectric constant (k) of 3.5 or above is formed in the sub-pad region as in the case of the semiconductor device in FIGS. 10A and 10B. The wires 62f and vias 64f are formed in the insulating film 60f, being connected with each other. Besides, an insulating film 66f is formed on each pad 4 and an opening 68f is formed in the location of the pad 4. The wires 62f and vias 64f are formed in regions other than the sub-pad region under the opening 68f, but not in the sub-pad region. Electrical connection with the pad 4 is secured by means of the wires 62f and vias 64f.

The above configuration allows the semiconductor device in FIGS. 20A and 20B to increase resistance to forces in the direction perpendicular to the chip edge 6 while maintaining resistance to forces in the pushing direction, and thereby prevent deterioration of shape in the sub-pad region during probing, as described in the second embodiment.

The reinforcement patterns in the low-k films 22f and 30f of the semiconductor device in FIGS. 19A to 19C may be combined with the reinforcement patterns consisting of tungsten vias according to the third embodiment. Specifically, in such a semiconductor device, the reinforcement pattern 70 consisting of tungsten vias is formed by penetrating the SiC film 36f and SiO₂ film 38f on the low-k film 30f in FIGS. 19A to 19C and the reinforcement pattern 72 is formed by penetrating the SiC film 44f and SiO₂ film 46f so as to connect to the reinforcement pattern 70. The reinforcement patterns 70 and 72 have the same shape and arrangement as the reinforcement vias 24f and 32f in the layers of the low-k films 22f and 30f when viewed from above.

In this way, by combining the reinforcement structure of the reinforcement patterns in the low-k films 22f and 30f according to the sixth embodiment with the reinforcement structure of the reinforcement patterns 70 and 72 made of tungsten vias described in the third embodiment, it is possible to further increase the resistance to forces exerted in the direction perpendicular to the chip edge 6 while maintaining the strength against forces in the pushing direction more reliably.

### Seventh Embodiment

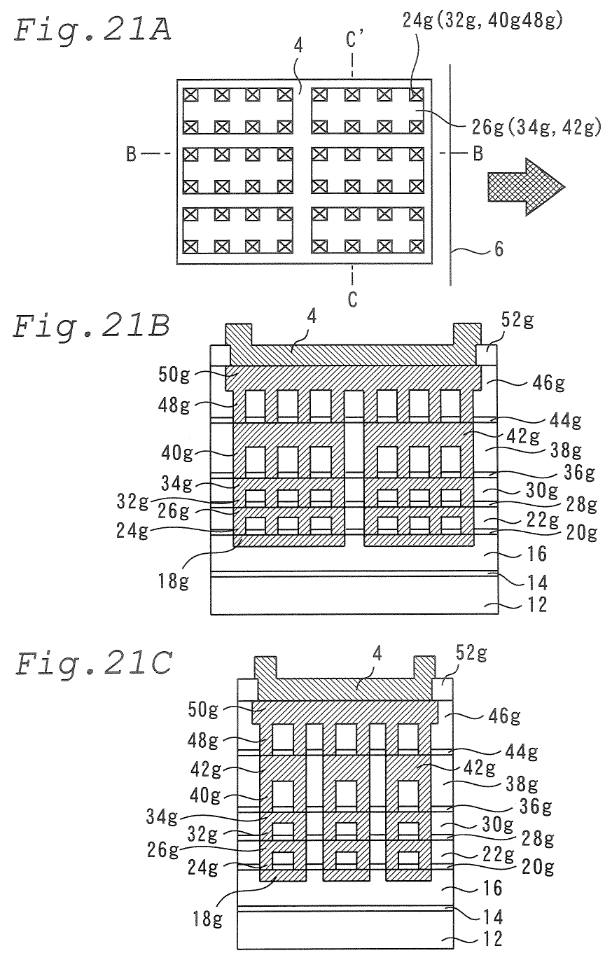

FIGS. 21A to 21C are schematic diagrams illustrating a structure near a sub-pad region of a semiconductor device according to a seventh embodiment of the present invention. FIG. 21A is a perspective front view showing mainly an arrangement of wires and vias in the sub-pad region, FIG. 21B is a sectional view taken along line B-B′ in FIG. 21A, and FIG. 21C is a sectional view taken along line C-C′ in FIG. 21A. The semiconductor device in FIGS. 21A to 21C is similar in configuration to the semiconductor device in FIGS. 2A to 2C and differs only in the shapes of wires and vias formed in insulating films.

Specifically, in the semiconductor device in FIGS. 21A to 21C, reinforcement wires 26g have a rectangular shape with the long sides placed in the direction perpendicular to the chip edge 6 when viewed from above. The short side of the reinforcement wires 26g in FIGS. 21A to 21C is equal to the one side of the reinforcement wires 26a in FIGS. 2A to 2C. A total of six reinforcement wires 26g are arranged in the sub-pad region: two columns in the direction perpendicular to the chip edge 6 and three rows in the direction parallel to the chip edge 6. The wires are elongated in the direction perpendicular to the chip edge 6 to increase their perpendicular-occupancy.

Four reinforcement vias 24g connected with one reinforcement wire 26g are arranged along the long sides of each reinforcement wire 26g and two rows of reinforcement vias 24g are arranged along the short sides thereof. In the entire sub-pad region, a total of 48 reinforcement vias 24g are arranged: eight columns in the direction perpendicular to the chip edge 6 and six rows along the chip edge 6. Thus, the reinforcement vias 24g are arranged such that their perpendicular-occupancy.

A reinforcement pattern of a similar configuration is formed in a layer of low-k film 30g above a low-k film 22g. Vias 40g and wires 42g are formed in a layer of SiO₂ film 38g on the low-k film 30g. They are similar in shape and arrangement to the reinforcement vias 24g and reinforcement wires 26g when viewed from above. Vias 48g similar in shape and arrangement to the vias 40g are formed in a layer of SiO₂ film 46g just under the pad 4. However, the uppermost wire 50g has a planar shape similar to that of the pad 4.

Incidentally, the semiconductor device in FIGS. 21A to 21C can be manufactured by the same technique as in FIG. 3 if mask patterns used for photolithography in Steps S114, S116, S124, S126, S134, S136, S144, and S146 in FIG. 3 are changed to those suitable for the structures of the vias and wires in FIGS. 21A to 21C.

Also, in the seventh embodiment, as long as reinforcement patterns such as those of the semiconductor device in FIGS. 21A to 21C are formed in the low-k films 22g and 30g, even if the wires and the like above them have other structures, it is possible to ensure resistance to forces exerted in the direction perpendicular to the chip edge 6.

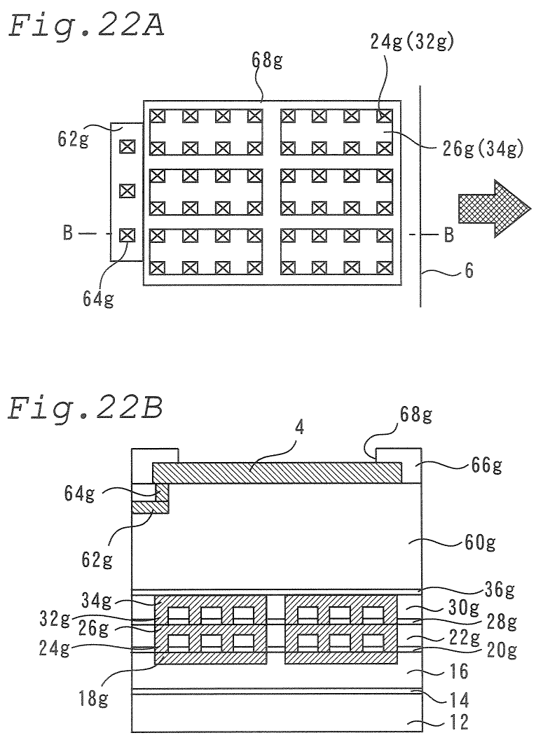

FIGS. 22A and 22B are schematic diagrams illustrating a structure near a sub-pad region of another semiconductor device according to the seventh embodiment of the present invention. FIG. 22A is a perspective front view showing mainly an arrangement of wires and vias in the sub-pad region and FIG. 22B is a sectional view taken along line B-B′ in FIG. 22A. The semiconductor device in FIGS. 22A and 22B has the same structure in terms of the sub-pad region as the semiconductor device in FIGS. 21A to 21C except that the semiconductor device in FIGS. 22A and 22B has an insulating film 60g instead of the layers of the SiO₂ film 38g, SiC film 44g, and SiO₂ film 46g on the low-k film 30g and that wires 62g and vias 64g are formed in the insulating film 60g.

Specifically, reinforcement patterns similar to those of the semiconductor device in FIGS. 21A to 21C are formed in the layers of the low-k films 22g and 30g of the semiconductor device in FIGS. 22A and 22B. The insulating film 60g with a dielectric constant (k) of 3.5 or above is formed in the sub-pad region as in the case of the second embodiment. The wires 62g and vias 64g are formed in the insulating film 60g, being connected with each other. Besides, an insulating film 66g is formed on each pad 4 and an opening 68g is formed in the location of the pad 4. The wires 62g and vias 64g are formed in regions other than the sub-pad region under the opening 68g, but not in the sub-pad region. Electrical connection with the pad 4 is secured by means of the wires 62g and vias 64g.

The above configuration allows the semiconductor device in FIGS. 22A and 22B to increase resistance to forces in the direction perpendicular to the chip edge 6 while maintaining resistance to forces in the pushing direction, and thereby prevent deterioration of shape in the sub-pad region during probing, as described in the second embodiment.

The reinforcement patterns in the low-k films 22g and 30g of the semiconductor device in FIGS. 21A to 21C may be combined with the reinforcement patterns consisting of tungsten vias according to the third embodiment. Specifically, in such a semiconductor device, the reinforcement pattern 70 consisting of tungsten vias is formed by penetrating the SiC film 36g and SiO₂ film 38g on the low-k film 30g in FIGS. 21A to 21C and the reinforcement pattern 72 is formed by penetrating the SiC film 44g and SiO₂ film 46g so as to connect to the reinforcement pattern 70. The reinforcement patterns 70 and 72 have the same shape and arrangement as the reinforcement vias 24g and 32g in the layers of the low-k films 22g and 30g when viewed from above.

In this way, by combining the reinforcement structure of the reinforcement patterns in the low-k films 22g and 30g according to the seventh embodiment with the reinforcement structure of the reinforcement patterns 70 and 72 made of tungsten vias described in the third embodiment, it is possible to further increase the resistance to forces exerted in the direction perpendicular to the chip edge 6 while maintaining the strength against forces in the pushing direction more reliably.

### Eighth Embodiment

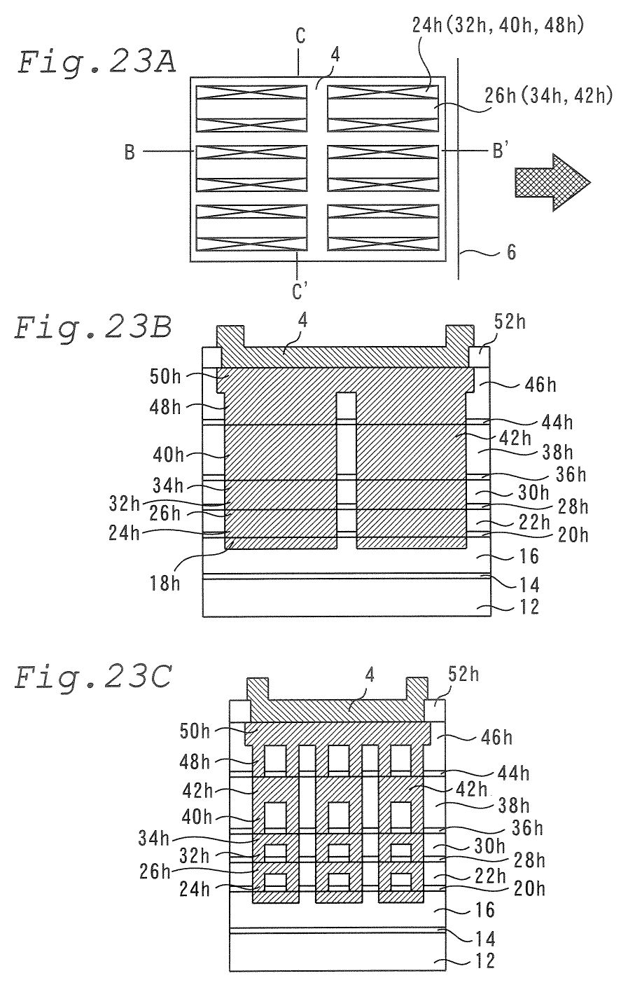

FIGS. 23A to 23C are schematic diagrams illustrating a structure near a sub-pad region of a semiconductor device according to an eighth embodiment of the present invention. FIG. 23A is a perspective front view showing mainly an arrangement of wires and vias in the sub-pad region, FIG. 23B is a sectional view taken along line B-B′ in FIG. 23A, and FIG. 23C is a sectional view taken along line C-C′ in FIG. 23A. The semiconductor device in FIGS. 23A to 23C is similar in configuration to the semiconductor device in FIGS. 2A to 2C and differs only in the shapes of wires and vias formed in insulating films.

Specifically, in the semiconductor device in FIGS. 23A to 23C, reinforcement wires 26h have a rectangular shape with the long sides placed in the direction perpendicular to the chip edge 6 when viewed from above as in the case of the semiconductor device in FIGS. 21A to 21C. The wires are elongated in the direction perpendicular to the chip edge 6 to increase their perpendicular-occupancy.

Reinforcement vias 24h are rectangular in shape with the long side equal to that of the reinforcement wires 26h. The reinforcement vias 24h are arranged along both long sides of each reinforcement wire 26h. In the entire sub-pad region, the reinforcement vias 24h have a rectangular shape with the long sides placed in the direction perpendicular to the chip edge 6 and have a higher perpendicular-occupancy. That is, they are arranged so as to increase their perpendicular-occupancy within an allowable range.

A reinforcement pattern of a similar configuration is formed in a layer of low-k film 30h above a low-k film 22h. Vias 40h and wires 42h are formed in a layer of SiO₂ film 38h on the low-k film 30h. They are similar in shape and arrangement to the reinforcement vias 24h and reinforcement wires 26h when viewed from above. Vias 48h similar in shape and arrangement to the vias 40h are formed in a layer of SiO₂ film 46h just under the pad 4. However, the uppermost wire 50h has a planar shape similar to that of the pad 4.

Incidentally, the semiconductor device in FIGS. 23A to 23C can be manufactured by the same technique as in FIG. 3 if mask patterns used for photolithography in Steps S114, S116, S124, S126, S134, S136, S144, and S146 in FIG. 3 are changed to those suitable for the structures of the vias and wires in FIGS. 23A to 23C.

Again, in the eighth embodiment, as long as reinforcement patterns such as those of the semiconductor device in FIGS. 23A to 23C are formed in the low-k films 22h and 30h, even if the wires and the like above them have other structures, it is possible to ensure resistance to forces exerted in the direction perpendicular to the chip edge 6.

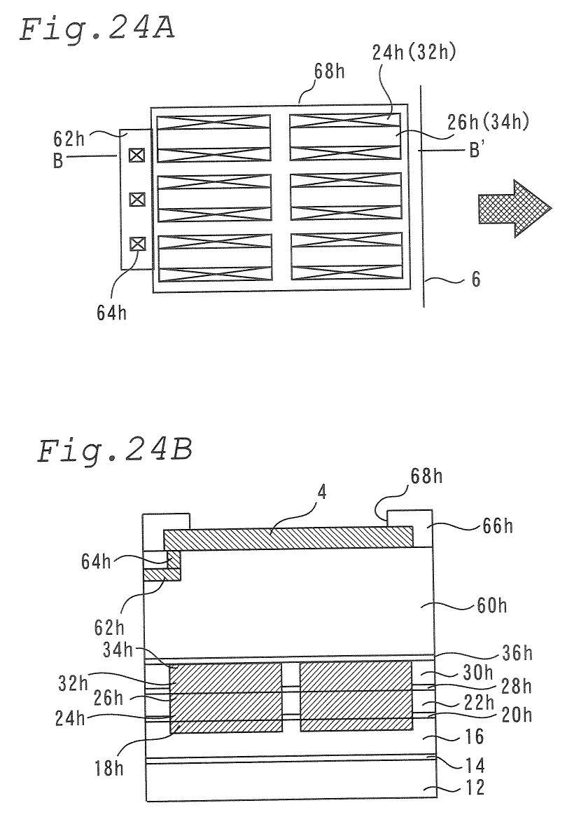

FIGS. 24A and 24B are schematic diagrams illustrating a structure near a sub-pad region of another semiconductor device according to the eighth embodiment of the present invention. FIG. 24A is a perspective front view showing mainly an arrangement of wires and vias in the sub-pad region and FIG. 24B is a sectional view taken along line B-B′ in FIG. 24A. The semiconductor device in FIGS. 24A and 24B has an insulating film 60h instead of the layers of the SiO₂ film 38h, SiC film 44h, and SiO₂ film 46h on the low-k film 30h in FIGS. 23A to 23C and wires 62h and vias 64h are formed in the insulating film 60h. Besides, an insulating film 66h is formed on each pad 4 and an opening 68h is formed in the location of the pad 4. The wires 62h and vias 64h are formed in regions other than the sub-pad region, but not in the sub-pad region. Electrical connection with the pad 4 is secured by means of the wires 62h and vias 64h.

The above configuration allows the semiconductor device in FIGS. 24A and 24B to increase resistance to forces in the direction perpendicular to the chip edge 6 while maintaining resistance to forces in the pushing direction, and thereby prevent deterioration of shape in the sub-pad region during probing, as described in the second embodiment.

The reinforcement patterns in the low-k films 22h and 30h of the semiconductor device in FIGS. 23A to 23C may be combined with the reinforcement patterns consisting of tungsten vias according to the third embodiment. Specifically, in such a semiconductor device, the reinforcement pattern 70 consisting of tungsten vias is formed by penetrating the SiC film 36h and SiO₂ film 38h on the low-k film 30h in FIGS. 23A to 23C and the reinforcement pattern 72 is formed by penetrating the SiC film 44h and SiO₂ film 46h so as to connect to the reinforcement pattern 70. The reinforcement patterns 70 and 72 have the same shape and arrangement as the reinforcement vias 24h and 32h when viewed from above.

In this way, by combining the reinforcement structure of the reinforcement patterns in the low-k films 22h and 30h according to the eighth embodiment with the reinforcement structure of the reinforcement patterns 70 and 72 made of tungsten vias described in the third embodiment, it is possible to further increase the resistance to forces exerted in the direction perpendicular to the chip edge 6 while maintaining the strength against forces in the pushing direction more reliably.

### Ninth Embodiment

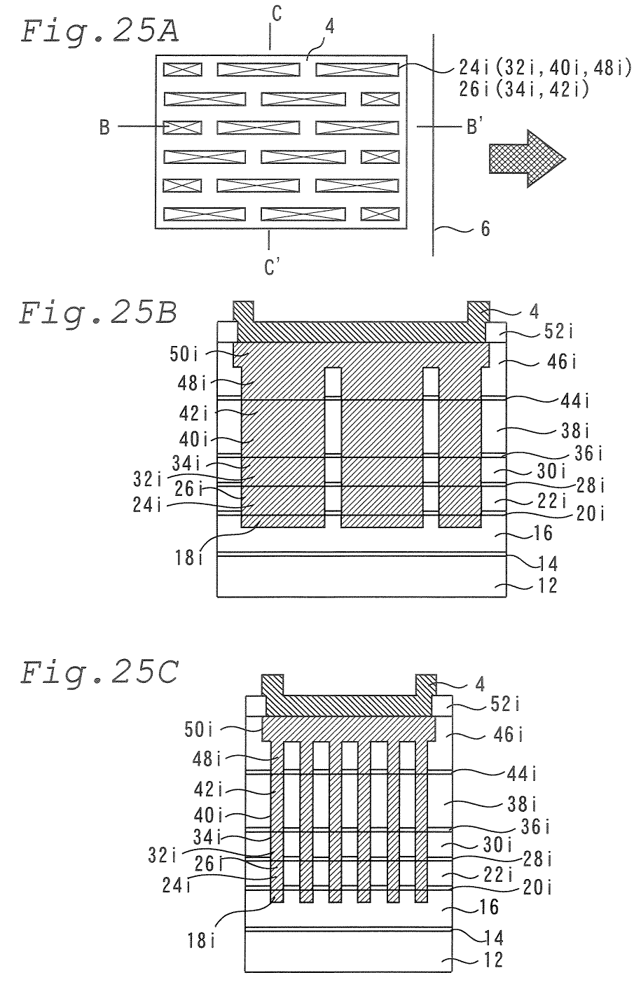

FIGS. 25A to 25C are schematic diagrams illustrating a structure near a sub-pad region of a semiconductor device according to a ninth embodiment of the present invention. FIG. 25A is a perspective front view showing mainly an arrangement of wires and vias in the sub-pad region, FIG. 25B is a sectional view taken along line B-B′ in FIG. 25A, and FIG. 25C is a sectional view taken along line C-C′ in FIG. 25A. The semiconductor device in FIGS. 25A to 25C is similar in configuration to the semiconductor device in FIGS. 2A to 2C and differs only in the shapes of wires and vias formed in insulating films.

Specifically, reinforcement patterns in a low-k film 22i of the semiconductor device in FIGS. 25A to 25C consist of reinforcement vias 24i and reinforcement wires 26i of the same shape. The reinforcement patterns have rectangular shapes with the long sides placed in the direction perpendicular to the chip edge 6 when viewed from above. The reinforcement patterns come in two types: a longer one and shorter one. The longer type is twice as long as the shorter type. The short sides of the reinforcement patterns are equal in length to the side of the reinforcement vias 24a of the semiconductor device in FIGS. 2A to 2C. In each sub-pad region, one short reinforcement pattern and two long reinforcement patterns are arranged in each row, i.e., in the direction perpendicular to the chip edge 6. In rows with the reinforcement patterns arranged in the direction perpendicular to the chip edge 6, one shorter reinforcement pattern is placed on the chip edge 6 side in one row and the next shorter pattern is placed on the opposite side in an adjacent row (in the up-and-down direction in FIGS. 25A to 25C).

In layers of low-k film 30i, SiO₂ film 38i, and SiO₂ film 46i above the low-k film 22i, vias and wire shave the same patterns and form the same shapes as those of the reinforcement vias 24i and reinforcement wires 26i. However, a wire 50i in the uppermost layer 46i has a planar shape similar to the wires 50a in FIGS. 2A to 2C.

The above configuration makes it possible to increase the occupancies of the vias and wires in the direction perpendicular to the chip edge 6. In the direction parallel to the chip edge 6, the patterns are reduced in size to keep down their occupancy. Thus, the perpendicular-occupancy of wires is increased within an allowable range. This makes it possible to increase resistance to forces in the direction perpendicular to the chip edge 6 while maintaining strength against forces in the pushing direction.

Incidentally, the semiconductor device in FIGS. 25A to 25C can be manufactured by the same technique as in FIG. 3 if mask patterns used for photolithography in Steps S114, S116, S124, S126, S134, S136, S144, and S146 in FIG. 3 are changed to those suitable for the structures of the vias and wires in FIGS. 25A to 25C.

Again, in the ninth embodiment, as long as reinforcement patterns such as those of the semiconductor device in FIGS. 25A to 25C are formed in the low-k films 22i and 30i, even if the wires and the like above them have other structures, it is possible to ensure resistance to forces exerted in the direction perpendicular to the chip edge 6.

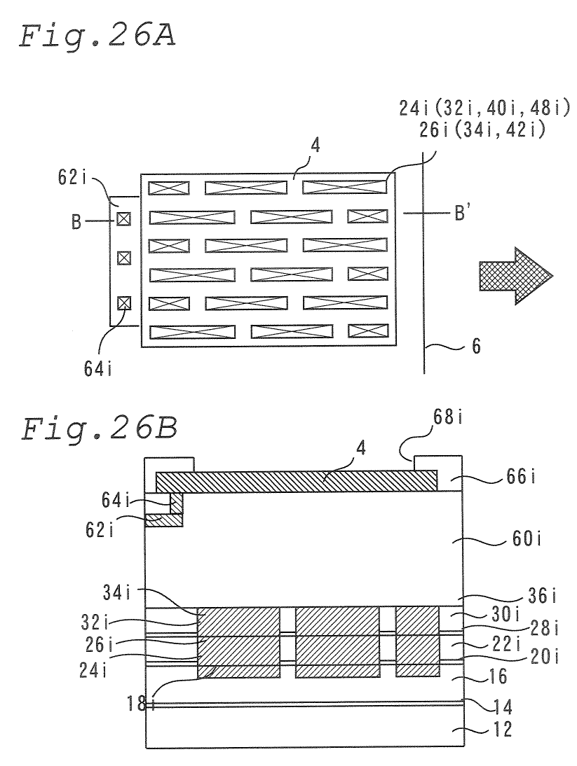

FIGS. 26A and 26B are schematic diagrams illustrating a structure near a sub-pad region of another semiconductor device according to the ninth embodiment of the present invention. FIG. 26A is a perspective front view showing mainly an arrangement of wires and vias in the sub-pad region and FIG. 26B is a sectional view taken along line B-B′ in FIG. 26A. The semiconductor device in FIGS. 26A and 26B has an insulating film 60i instead of the layers of the SiO₂ film 38i, SiC film 44i, and SiO₂ film 46i on the low-k film 30i in FIG. 26B and wires 62i and vias 64i are formed in the insulating film 60i. Besides, an insulating film 66i is formed on each pad 4 and an opening 68i is formed in the location of the pad 4. The wires 62i and vias 64i are formed in regions other than the sub-pad region, but not in the sub-pad region. Electrical connection with the pad 4 is secured by means of the wires 62i and vias 64i.

The above configuration allows the semiconductor device in FIGS. 26A and 26B to increase resistance to forces in the direction perpendicular to the chip edge 6 while maintaining resistance to forces in the pushing direction, and thereby prevent deterioration of shape in the sub-pad region during probing, as described in the second embodiment.

The reinforcement patterns in the low-k films 22i and 30i of the semiconductor device in FIGS. 25A to 25C may be combined with the reinforcement patterns consisting of tungsten vias according to the third embodiment. Specifically, in such a semiconductor device, the reinforcement pattern 70 consisting of tungsten vias is formed by penetrating the SiC film 36i and SiO₂ film 38i on the low-k film 30i in FIGS. 25A to 25C and the reinforcement pattern 72 is formed by penetrating the SiC film 44i and SiO₂ film 46i so as to connect to the reinforcement pattern 70. The reinforcement patterns 70 and 72 have the same shape and arrangement as the reinforcement vias 24i and 32i and reinforcement wires 26i and 34i when viewed from above.

In this way, by combining the reinforcement structure of the reinforcement patterns in the low-k films 22i and 30i according to the ninth embodiment with the reinforcement structure of the reinforcement patterns 70 and 72 made of tungsten vias described in the third embodiment, it is possible to further increase the resistance to forces exerted in the direction perpendicular to the chip edge 6 while maintaining the strength against forces in the pushing direction more reliably.

### Tenth Embodiment

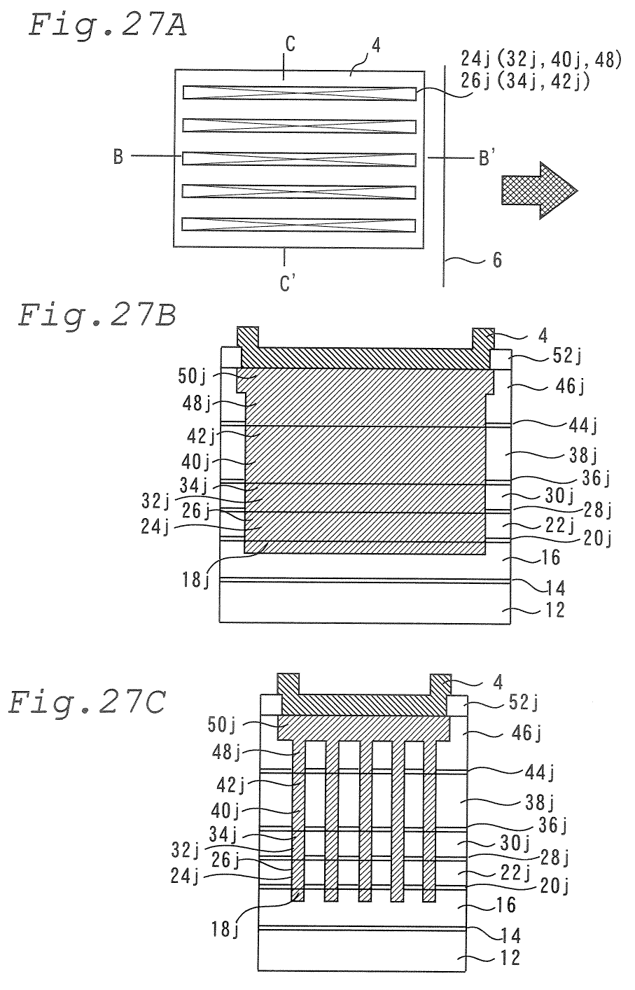

FIGS. 27A to 27C are schematic diagrams illustrating a structure near a sub-pad region of a semiconductor device according to a tenth embodiment of the present invention. FIG. 27A is a perspective front view showing mainly an arrangement of wires and vias in the sub-pad region, FIG. 27B is a sectional view taken along line B-B′ in FIG. 27A, and FIG. 27C is a sectional view taken along line C-C′ in FIG. 27A. The semiconductor device in FIGS. 27A to 27C is similar in configuration to the semiconductor device in FIGS. 2A to 2C and differs only in the shapes of wires and vias formed in insulating films.

Specifically, reinforcement patterns in the layer of a low-k film 22j of the semiconductor device in FIGS. 27A to 27C consist of reinforcement vias 24j and reinforcement wires 26j of the same shape. The reinforcement pattern has a rectangular shape with the long sides placed in the direction perpendicular to the chip edge 6 when viewed from above. The short side of the reinforcement pattern is equal in length to the side of the reinforcement vias 24a of the semiconductor device in FIGS. 2A to 2C. In each sub-pad region, one column of reinforcement patterns is placed along the chip edge 6 with each row containing a single reinforcement pattern. That is, the long sides of the reinforcement patterns are elongated in the direction perpendicular to the chip edge 6 within an allowable range.

In layers of low-k film 30j, SiO₂ film 38j, and SiO₂ film 46j above the layer of the low-k film 22j, vias and wires have the same patterns and form the same shapes as the reinforcement vias 24j and reinforcement wires 26j. However, a wire 50j in the uppermost layer 46j has a planar shape similar to wires 50a in FIGS. 2A to 2C.

In this way, the reinforcement patterns are elongated in the direction perpendicular to the chip edge 6 within the upper limit of their occupancy. This increases the perpendicular-occupancy. On the other hand, the reinforcement patterns are shortened in the direction parallel to the chip edge 6 to keep down their occupancy. This structure maximizes the perpendicular-occupancy of the reinforcement within an allowable range. This makes it possible to increase resistance to forces in the direction perpendicular to the chip edge 6 while maintaining strength against forces in the pushing direction.

Incidentally, the semiconductor device in FIGS. 27A to 27C can be manufactured by the same technique as in FIG. 3 if mask patterns used for photolithography in Steps S114, S116, S124, S126, S134, S136, S144, and S146 in FIG. 3 are changed to those suitable for the structures of the vias and wires in FIGS. 27A to 27C.

Again, in the tenth embodiment, as long as reinforcement patterns such as those of the semiconductor device in FIGS. 27A to 27C are formed in the low-k films 22j and 30j, even if the wires and the like above them have other structures, it is possible to ensure resistance to forces exerted in the direction perpendicular to the chip edge 6.

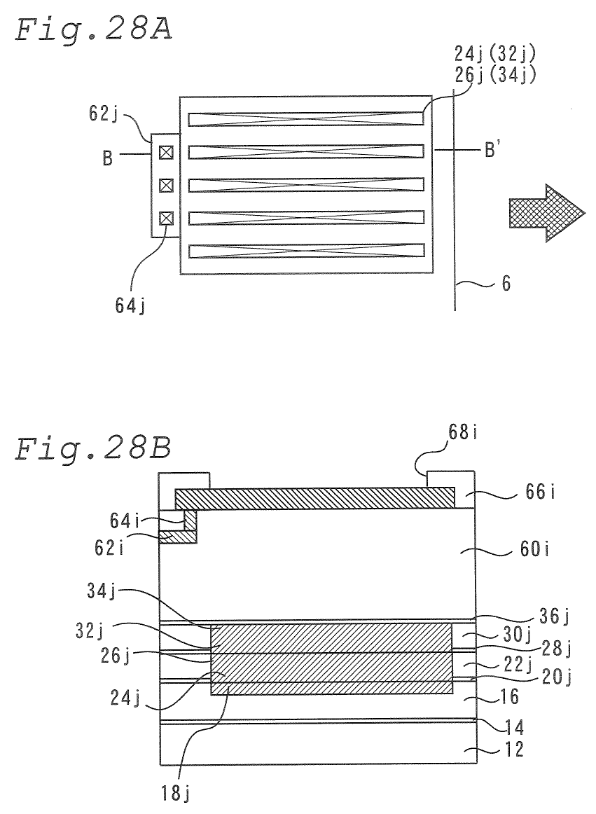

FIGS. 28A and 28B are schematic diagrams illustrating a structure near a sub-pad region of another semiconductor device according to the tenth embodiment of the present invention. FIG. 28A is a perspective front view showing mainly an arrangement of wires and vias in the sub-pad region and FIG. 28B is a sectional view taken along line B-B′ in FIG. 28A. The semiconductor device in FIGS. 28A and 28B has an insulating film 60j instead of the layers of the SiO₂ film 38j, SiC film 44j, and SiO₂ film 46j on the low-k film 30j in FIGS. 28A and 28B and wires 62j and vias 64j are formed in the insulating film 60j. Besides, an insulating film 66j is formed on each pad 4 and an opening 68j is formed in the location of the pad 4. The wires 62j and vias 64j are formed in regions other than the sub-pad region, but not in the sub-pad region. Electrical connection with the pad 4 is secured by means of the wires 62j and vias 64j.

The above configuration allows the semiconductor device in FIGS. 28A and 28B to increase resistance to forces in the direction perpendicular to the chip edge 6 while maintaining resistance to forces in the pushing direction, and thereby prevent deterioration of shape in the sub-pad region during probing, as described in the second embodiment.

The reinforcement patterns in the low-k films 22j and 30j of the semiconductor device in FIGS. 27A to 27C may be combined with the reinforcement patterns consisting of tungsten vias according to the third embodiment. Specifically, in such a semiconductor device, the reinforcement pattern 70 consisting of tungsten vias is formed by penetrating the SiC film 36j and SiO₂ film 38j on the low-k film 30j in FIGS. 27A to 27C and the reinforcement pattern 72 is formed by penetrating the SiC film 44j and SiO2 film 46j so as to connect to the reinforcement pattern 70. The reinforcement patterns 70 and 72 have the same shape and arrangement as the reinforcement vias 24j and 32j and reinforcement wires 26j and 34j when viewed from above.

In this way, by combining the reinforcement structure of the reinforcement patterns in the low-k films 22j and 30j according to the tenth embodiment with the reinforcement structure of the reinforcement patterns 70 and 72 made of tungsten vias described in the third embodiment, it is possible to further increase the resistance to forces exerted in the direction perpendicular to the chip edge 6 while maintaining the strength against forces in the pushing direction more reliably.

Although FIG. 1 shows only a single line of pads 4 along each edge of the semiconductor chip 2, the present invention is not limited to this and two or more lines of pads 4 may be arranged along each edge of the semiconductor chip 2. In that case, although the structure according to any of the first to tenth embodiments may be formed in all the sub-pad regions, it is sufficient if the reinforcement structure according to any of the first to tenth embodiments is formed at least in the outermost sub-pad regions.

Also, the drawings in the above embodiments show only schematically that wires and vias are arranged in such a way as to increase their perpendicular-occupancy. Thus, according to the present invention, the numbers of wires and vias actually formed are not limited to the illustrated numbers.

Also, the numbers, quantities, amounts, or ranges of elements mentioned in the above embodiments are not intended to be limiting unless specifically noted or unless considered to be obviously the only possible ones in principle. Also, the structures described in the embodiments, steps in methods, and the like are not necessarily essential to the present invention unless specifically noted or unless considered to be obviously the only possible ones in principle.

The features and the advantages of the present invention as described above may be summarized as follows.

According to the present invention, a reinforcement pattern is formed in that part of an insulating film which is located in a region underneath each pad in a semiconductor device. In the region underneath each pad, the occupancy of the reinforcement pattern in the first insulating film is within a predetermined range permitted for the region underneath each pad. Also, the perpendicular-occupancy of the reinforcement is higher than the parallel-occupancy of the reinforcement. That is, within a limited range of occupancy, emphasis is placed on the occupancy of the pattern in the direction perpendicular to the chip edge. Thus, it is possible to provide a reliable semiconductor device by preventing drops in resistance to forces in the pushing direction and increasing resistance to forces in the direction perpendicular to the chip edge.

Obviously many modifications and variations of the present invention are possible in the light of the above teachings. It is therefore to be understood that within the scope of the appended claims the invention may by practiced otherwise than as specifically described.

The entire disclosures of a Japanese Patent Application No. 2005-337355, filed on Nov. 22, 2005 including specifications, claims, drawings and summaries, on which the Convention priorities of the present application are based, are incorporated herein by references in its entirety.

1. A semiconductor device comprising:
a semiconductor chip which comprises at least one layer of first insulating film formed on a substrate, and a plurality of pads arranged on a layer higher than the first insulating film,
wherein the plurality of pads are arranged parallel to a chip edge of the semiconductor chip,
the first insulating film has a reinforcement pattern in a region underneath each of the plurality of pads;
in the region underneath each pad, occupancy of the reinforcement pattern in the first insulating film is within a range permitted for the region underneath each pad and occupancy of the reinforcement pattern in a whole area of a row where the reinforcement pattern is arranged in a line in a direction perpendicular to the predetermined chip edge is higher than occupancy of the reinforcement pattern in a whole area of a row where the reinforcement pattern is arranged in a line in a direction parallel to the chip edge.

2. The semiconductor device according to claim 1, wherein in the region underneath each pad, the occupancy of the reinforcement pattern in the first insulating film is 80% or below.

3. The semiconductor device according to claim 1, wherein the first insulating film is a low-dielectric film comprising laminated layers; and
the reinforcement pattern is formed in all the layers of the low-dielectric film.

4. The semiconductor device according to claim 1, further comprising, in a layer just under the pads, a second insulating film with a thickness of at least 1.0 μm or above and a dielectric constant of 3.5 or above.

5. The semiconductor device according to claim 1, further comprising:
a third insulating film formed between the first insulating film and the pads; and
reinforcement vias made of tungsten, formed in the third insulating film, and connected to the pads.

6. The semiconductor device according to claim 1, wherein:
the plurality of pads are arranged in two or more rows parallel to the chip edge; and
the reinforcement pattern is formed in region underneath each pad arranged in the outermost part of the semiconductor chip out of the pads arranged in two or more rows.

7. The semiconductor device according to claim 1, further comprising:
a plurality of vias formed in a layer of the first insulating film, wherein
the reinforcement pattern includes vias arranged in the region underneath each pad out of the plurality of vias.

8. The semiconductor device according to claim 1, further comprising:
a plurality of wires formed in a layer of the first insulating film, wherein
the reinforcement pattern includes wires arranged in the region underneath each pad out of the plurality of wires.

9. The semiconductor device according to claim 1, further comprising:
a plurality of vias and a plurality of wires formed in a layer of the first insulating film, wherein
the reinforcement pattern comprises wires arranged in the region underneath each pad and vias connected to the wires.

10. The semiconductor device according to claim 1, further comprising:
a plurality of vias formed in a layer of the first insulating film,
wherein the reinforcement pattern includes vias arranged in the region underneath each pad out of the plurality of vias; and
the vias in the reinforcement pattern is rectangular in shape with a long side placed in a direction perpendicular to the predetermined chip edge when viewed from above.

11. The semiconductor device according to claim 1, further comprising:
a plurality of wires formed in a layer of the first insulating film,
wherein the reinforcement pattern includes wires arranged in the region underneath each pad out of the plurality of wires; and
the wires in the reinforcement pattern are rectangular in shape with a long side placed in a direction perpendicular to the predetermined chip edge when viewed from above.

12. The semiconductor device according to claim 1, further comprising:
a plurality of vias and a plurality of wires formed in a layer of the first insulating film,
wherein the reinforcement pattern comprises wires arranged in the region underneath each pad and vias connected to the wires, and
the wires and vias in the reinforcement pattern have the same rectangular shape with a long side placed in a direction perpendicular to the predetermined chip edge when viewed from above.
